(19) United States
(12) Patent Application Publication
(10) Pub. No.: US 2014/0298126 A1
(43) Pub. Date: Oct. 2, 2014

(54) LATCH CIRCUIT, SCAN TEST CIRCUIT AND LATCH CIRCUIT CONTROL METHOD

(71) Applicant: FUJITSU LIMITED, Kawasaki-shi (JP)

(72) Inventor: Itsumi Sugiyama, Kawasaki (JP)

(73) Assignee: FUJITSU LIMITED, Kawasaki-shi (JP)

(21) Appl. No.: 14/225,620

(22) Filed: Mar. 26, 2014

(30) Foreign Application Priority Data
Apr. 2, 2013 (JP) 2013-077055

(51) Int. Cl. H03K 3/0233; G01R 31/3177

(52) U.S. Cl. CPC H03K 3/0233; G01R 31/3177
USPC 714/726; 327/199

(57) ABSTRACT

A latch circuit includes: a data latch that holds data that has been input according to a first control signal or a second control signal; and a latch controller that includes a first input terminal to which a first operation signal is input, the first operation signal operating the data latch in a first scan method, and a second input terminal to which a second operation signal is input, the second operation signal operating the data latch in a second scan method; wherein when a prescribed value is input to the first input terminal, the latch controller outputs the second control signal to control the data latch, and when a prescribed value is input to the second input terminal, the latch controller outputs the first control signal to control the data latch.

### CROSS-REFERENCE TO RELATED APPLICATION

This application is based upon and claims the benefit of priority of the prior Japanese Patent Application No. 2013-077055, filed on Apr. 2, 2013, the entire contents of which are incorporated herein by reference.

### FIELD

The embodiments discussed herein are related to a latch circuit and a scan test circuit.

### BACKGROUND

In a semiconductor integrated circuit, a scan test or another test is executed for troubleshooting of a built-in circuit and other purposes. To execute a scan test, a scan test circuit is formed by using latch circuits, flip-flop circuits including latch circuits (latch circuits and flip-flop circuits including latch circuits will be collectively referred to below as latch circuits), and other circuits.

Scan methods used to execute a scan test include the level-sensitive scan design (LSSD) method and multiplexer D (MUX-D) method. Which of the LSSD method and MUX-D method is to be used as the method of scanning a semiconductor integrated circuit is determined depending on the latch circuits formed in the semiconductor integrated circuit. In a latch circuit to which the MUX-D method, for example, is applied, a scan-mode signal and a scan clock signal are used as control signals. In a latch circuit to which the LSSD method is applied, a system clock and two types of scan clock signals, which differ from the system clock, are used as control signals; the time durations of the two types of scan clock signals differ from each other.

When a semiconductor integrated circuit is designed, circuit blocks created in advance are diverted to improve design efficiency. Latch circuits to which the MUX-D method is applied and latch circuits to which the LSSD method is applied may be placed in a semiconductor integrated circuit designed by using circuit blocks created in advance.

In view of this, there is a method available to a semiconductor integrated circuit in which both latch circuits in the MUX-D method and latch circuits in the LSSD method are placed; in this method, a scan test circuit to which control signals in the MUX-D method are applied and a scan test circuit to which control signals in the LSSD method are applied are formed. In this semiconductor integrated circuit, the scan test circuit in the MUX-D method and the scan test circuit in the LSSD method operate independently.

In another method available to a semiconductor integrated circuit in which both latch circuits in the MUX-D method and latch circuits in the LSSD method are placed, an LSSD interface is used to create two types of individual clock signals, the time durations of which differ from each other, from a system clock signal in the MUX-D method. When an LSSD storage element operates in response to a clock signal supplied through the LSSD interface, the LSSD storage element can be used in the same scan test circuit in which a non-LSSD storage element in the MUX-D method is used.

The following are reference documents.
[Document 1] Japanese Laid-open Patent Publication No. 11-142477, and
[Document 2] Japanese National Publication of International Patent Application No. 2003-523520.

### SUMMARY

According to an aspect of the invention, a latch circuit includes: a data latch that holds data that has been input according to a first control signal or a second control signal; and a latch controller that includes a first input terminal to which a first operation signal is input, the first operation signal operating the data latch in a first scan method, and a second input terminal to which a second operation signal is input, the second operation signal operating the data latch in a second scan method; wherein when a prescribed value is input to the first input terminal and the second operation signal is input to the second input terminal, the latch controller outputs the second control signal to control the data latch, and when a prescribed value is input to the second input terminal and the first operation signal is input to the first input terminal, the latch controller outputs the first control signal to control the data latch.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a functional block diagram of the main elements of a semiconductor integrated circuit in a first embodiment;

FIG. 2 is a block diagram of a latch circuit in the first embodiment;

FIG. 3 is a block diagram illustrating an example of a data latching part in the latch circuit in the first embodiment;

FIG. 4 is a block diagram illustrating an example of a latch control part in the latch circuit in the first embodiment;

FIG. 5 is a block diagram illustrating an example of a connection to operate the latch circuit in the first embodiment in the LSSD method;

FIG. 6 is a block diagram illustrating the latch signals in FIG. 5;

FIG. 7 is a block diagram illustrating an example of a connection to operate the latch circuit in the first embodiment in the MUX-D method;

FIG. 8 is a block diagram illustrating the latch signals in FIG. 7;

FIG. 9 is a block diagram illustrating an example of a connection to operate the latch circuit in the first embodiment in the LSSD method;

FIG. 10 is a block diagram illustrating another example of a connection to operate the latch circuit in the first embodiment in the MUX-D method;

FIG. 11 is a functional block diagram of the main elements of a semiconductor integrated circuit in a second embodiment;

FIG. 12 is a block diagram illustrating an example of a signal creating part in the second embodiment;

FIG. 13 is a timing diagram illustrating an example of an operation of the signal creating part in FIG. 12;

FIG. 14 illustrates an example of a scan test circuit in which a latch control part in the second embodiment is used;

FIG. 15 is a functional block diagram of the main elements of a semiconductor integrated circuit in a third embodiment;

FIG. 16 is a block diagram illustrating an example of a signal creating part in the third embodiment;

FIG. 17 is a timing diagram illustrating an example of an operation of the signal creating part in FIG. 15; and

FIG. 18 illustrates an example of a scan test circuit in which a latch control part in the third embodiment is used.

### DESCRIPTION OF EMBODIMENTS

Examples of embodiments of the technology in the present disclosure will be described in detail with reference to the drawings.

### First Embodiment

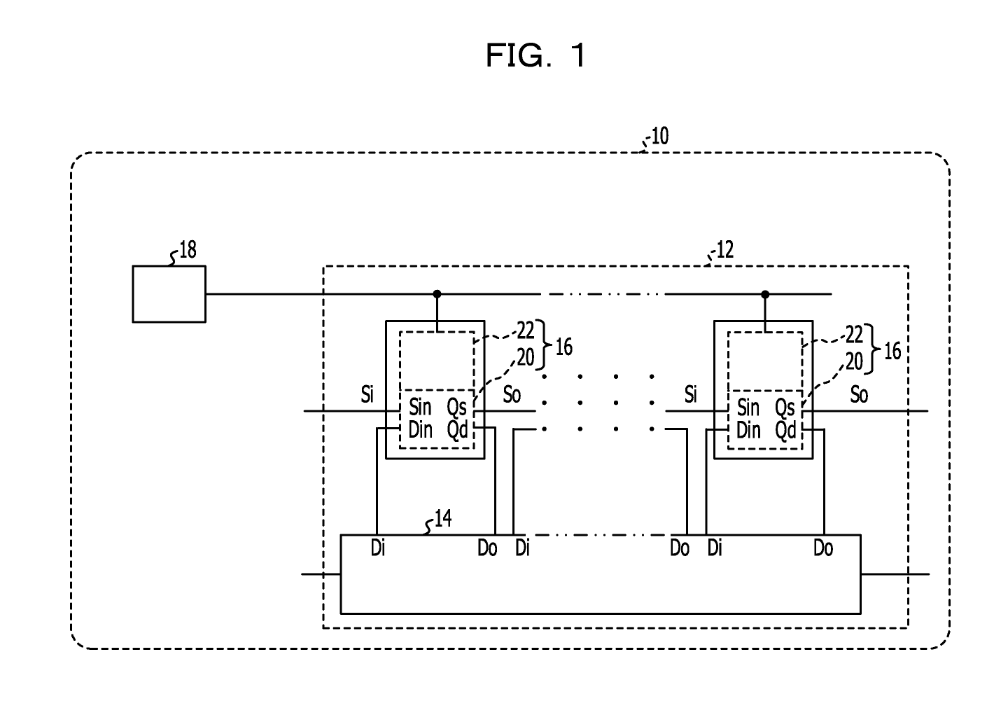

FIG. 1 illustrates the main elements of a semiconductor integrated circuit 10 in a first embodiment. The semiconductor integrated circuit 10 in the first embodiment functions as an example of a semiconductor integrated circuit. A large-scale integrated circuit (LSI) or very large-scale integrated circuit (VLSI) is used as the semiconductor integrated circuit 10. Alternatively, an ultra very large-scale integrated circuit (ultra VLSI, that is, ULSI), which has a higher integration density than the VLSI, or the like may be used as the semiconductor integrated circuit 10. The semiconductor integrated circuit 10 includes a scan test circuit 12, which includes circuit elements that detect a fault in a scan test. The scan test circuit 12 in the first embodiment functions as an example of a scan test circuit.

The semiconductor integrated circuit 10 includes a combinational logic circuit 14. The semiconductor integrated circuit 10 also includes a plurality of latch circuits 16. When the semiconductor integrated circuit 10 operates normally, each latch circuit 16 operates as, for example, a storage element. The latch circuit 16 holds data Di, which is output from the combinational logic circuit 14 to an input terminal Din of the latch circuit 16. The latch circuit 16 outputs the data Di, which the latch circuit 16 has held, from its output terminal Qd to the combinational logic circuit 14 as data Do.

In the semiconductor integrated circuit 10, troubleshooting of circuits and other tests are executed by a scan test method. In the scan test circuit 12, a scan chain is formed by using, for example, transmission gates to switch connections to the plurality of latch circuits 16 provided for a scan test. The latch circuit 16 in the first embodiment functions as an example of a latch circuit.

In the scan test circuit 12, the plurality of latch circuits 16, which form a scan chain, function as a shift register during a scan test. The semiconductor integrated circuit 10 includes a scan control part 18, which controls the operation of each latch circuit 16 in the scan test circuit 12 during execution of a scan test. Although, in the first embodiment, the semiconductor integrated circuit 10 will be described as internally including the scan control part 18, this is not a limitation. A test apparatus that function as the scan control part 18 may be externally connected to the semiconductor integrated circuit 10. The latch circuit 16 in the first embodiment functions as an example of a latch circuit.

The latch circuit 16 includes an input terminal Din to which data Di is input and an input terminal Sin to which scan data Si is input. The latch circuit 16 also includes an output terminal Qd from which data Do is output and an output terminal Qs from which scan data So is output. Data Di and scan data Si in the first embodiment respectively function as first data and second data. Data Do and scan data So in the first embodiment function as output data.

In the scan test circuit 12, the input terminal Sin of each latch circuit 16 is connected to the output terminal Qs of the latch circuit 16 on the immediately upstream side of the scan chain, and the output terminal Qs is connected to the input terminal Sin of the latch circuit 16 on the immediately downstream side of the scan chain. The latch circuit 16 retrieves scan data Si that has been input to its input terminal Sin and stores the scan data Si (this operation will be referred to below as a latch). The latch circuit 16 outputs the scan data Si that it holds from its output terminal Qs to the latch circuit 16 at the later stage as scan data So at a predetermined timing.

Scan test methods applicable to the semiconductor integrated circuit 10 include the multiplexer D (MUX-D) method and level-sensitive scan design (LSSD) method. In the MUX-D method, a system clock signal (referred to below as the clock signal CLK) and a scan mode signal (referred to below as the mode signal SM) are used as control signals that control the operation of the latch circuit 16. In the LSSD method, the clock signal CLK and two types of scan clock signals, the time durations of which differ from each other, are used as control signals that control the operation of the latch circuit 16 (one of the two scan clock signals will be referred to below as the scan clock signal ACLK and the other will be referred to below as the scan clock signal BCLK). The LSSD method in the first embodiment functions as one of a first scan method and a second scan method. The MUX-D method in the first embodiment functions as the other of the first scan method and second scan method. The mode signal SM in the first embodiment functions as one of a first operation signal and a second operation signal. The scan clock signals ACLK and BCLK in the first embodiment function as the other of the first operation signal and second operation signal.

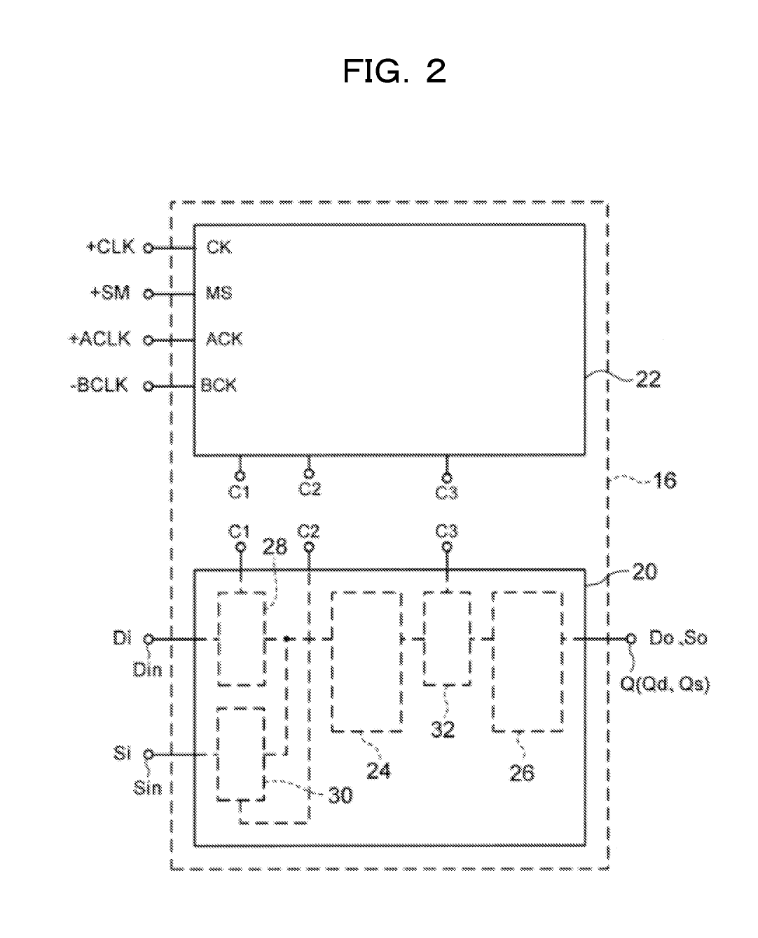

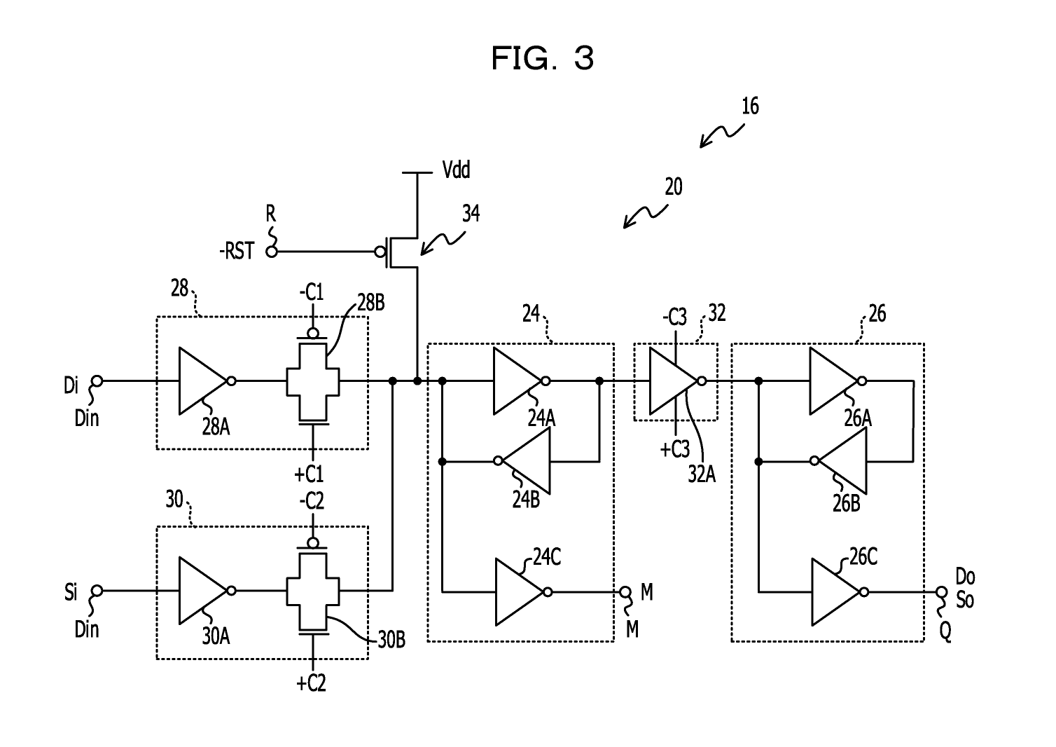

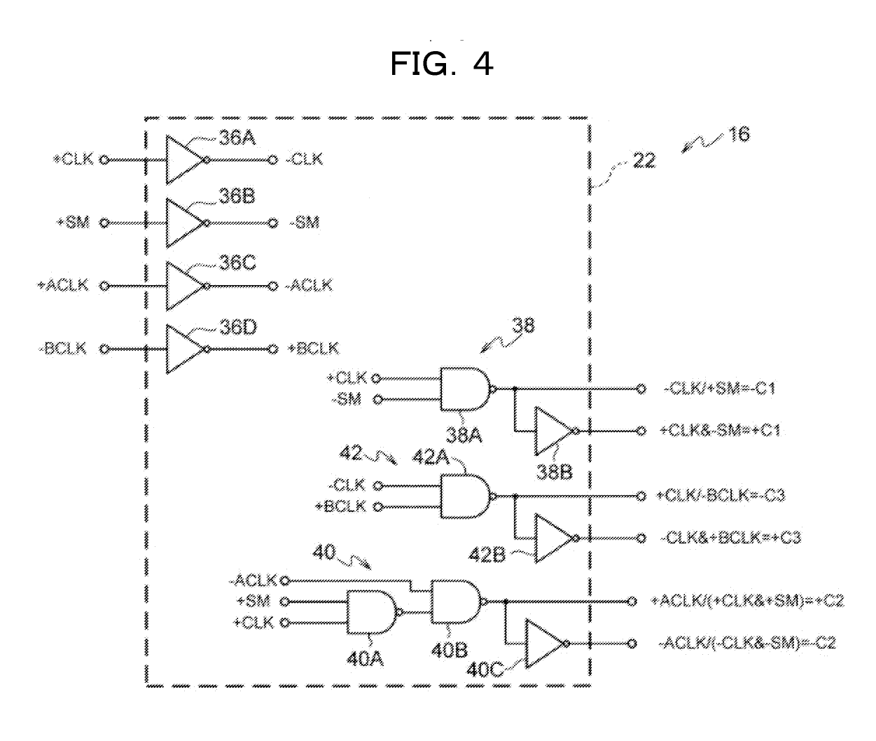

FIG. 2 is a functional block diagram of the latch circuit 16. The latch circuit 16 includes a data latching part 20 and a latch control part 22. FIG. 3 illustrates an example of the data latching part 20 in the latch circuit 16, and FIG. 4 illustrates an example of the latch control part 22 in the latch circuit 16. The data latching part 20 in the first embodiment functions as a data latching part, and the latch control part 22 in the first embodiment functions as a latch control part.

As illustrated in FIGS. 2 and 3, the data latching part 20 has input terminals Din and Sin and an output terminal Q. The latch circuit 16 uses the input terminal Din to receive data Di and the input terminal Sin to receive scan data Si. The latch circuit 16 uses the output terminal Q as the output terminal Qd from which data Do is output and as the output terminal Qs from which scan data So is output.

The data latching part 20 includes a first latch part 24 and a second latch part 26. The first latch part 24 in the first embodiment functions as a first latch part or latch. The second latch part 26 in the first embodiment functions as a second latch part or latch.

The first latch part 24 in the data latching part 20 functions as a master latch. It latches data Di input through the input terminal Din or scan data Si input through the input terminal Sin. The second latch part 26 in the data latching part 20 functions as a slave latch. It receives the data Di or scan data Si latched by the first latch part 24 and latches the data Di or scan data Si. The latch circuit 16 outputs the data Di or scan data Si latched in the second latch part 26 from the output terminal Q. Accordingly, the data latching part 20 has basic functions of an ordinary latch circuit.

The data latching part 20 has a switch part 28 between the input terminal Din and the first latch part 24, a switch part 30 between the input terminal Sin and the first latch part 24, and a switch part 32 between the first latch part 24 and the second latch part 26. The switch part 28 in the first embodiment functions as a first switch part. The switch part 30 in the first embodiment functions as a second switch part. The switch part 32 in the first embodiment functions as a third switch part.

The switch part 28 is selectively brought into a conductive state and a non-conductive state (referred to below as “turned on” and “turned off”) by an operation control signal C1. When the switch part 28 is turned on, the data latching part 20 latches data Di input through the input terminal Din in the first latch part 24. The switch part 30 is selectively turned on off by an operation control signal C2. When the switch part 30 is turned on, the data latching part 20 latches scan data Si input through the input terminal Sin in the first latch part 24.

The switch part 32 is selectively turned on off by an operation control signal C3. When the switch part 32 is turned on, the data latching part 20 latches, in the second latch part 26, the data Di or scan data Si that has been latched in the first latch part 24. The operation control signals C1 to C3 in the first embodiment function as a first control signal and a second control signal. The operation control signal C1 in the first embodiment functions as a first operation control signal and a fourth operation control signal. The operation control signal C2 in the first embodiment functions as a second operation control signal and a fifth operation control signal. The operation control signal C3 in the first embodiment functions as a third operation control signal and a sixth operation control signal.

As illustrated in FIG. 3, the first latch part 24, for example, includes an inverter circuit 24A and an inverter circuit 24B. The first latch part 24 latches data Di or scan data Si in the inverter circuits 24A and 24B. The first latch part 24 may output the data Di or scan data Si latched in the inverter circuits 24A and 24B through, for example, the inverter circuit 24C from an output terminal M as data Mo.

The second latch part 26 includes an inverter circuit 26A and an inverter circuit 26B. The second latch part 26 latches data Di or scan data Si in the inverter circuits 26A and 26B. The second latch part 26 also includes an inverter circuit 26C. The data Di or scan data Si latched in the inverter circuits 26A and 26B is output through the inverter circuit 26C to the output terminal Q.

The switch part 28 includes an inverter circuit 28A and a transmission gate (TG) 28B. The switch part 30 includes an inverter circuit 30A and a TG 30B. The TG 28B operates on complementary operation control signals +C1 and −C1, which are input as the operation control signal C1. The TG 30B operates on complementary operation control signals +C2 and −C2, which are input as the operation control signal C2. The TG 30B is turned on and is brought into a conductive state during a scan test. The TG 28B is turned on and is brought into a conductive state when a data path is operated during a normal operation or a scan test (when a data path is activated after a value for a scan shift has been set). In the descriptions below, positive logic signals will be indicated by a plus sign (+) and negative logic signals will be indicated by a minus sign (−).

In the data latching part 20, when the operation control signal +C1 input to the TG 28B becomes a logic one (+C1=1, referred to below as the H level), the first latch part 24 retrieves data Di input through the input terminal Din and latches the data Di. When the operation control signal +C2 input to the TG 30B becomes the H level (+C2=1), the first latch part 24 retrieves the scan data Si input through the input terminal Sin and latches the scan data Si.

The switch part 32 includes, for example, a clocked inverter circuit 32A. The clocked inverter circuit 32A is turned on and off by complementary operation control signals +C3 and −C3, which are input as the operation control signal C3. When the operation control signal +C3 becomes the H level (+C3=1), the clocked inverter circuit 32A is turned on, at which time the clocked inverter circuit 32A inverts the data Di or scan data Si latched in the first latch part 24 and inputs the inverted data to the second latch part 26. The second latch part 26 latches the data Di or scan data Si received from the clocked inverter circuit 32A.

As illustrated in FIG. 3, the data latching part 20 in the latch circuit 16 includes a reset terminal R. When the reset terminal R of the data latching part 20 is connected to a gate G of a positive channel metal-oxide semiconductor (PMOS) transistor 34 and a reset signal −RST becomes the L level, the first latch part 24 and second latch part 26 in the data latching part 20 are reset.

In a scan test in the MUX-D method, the clock signal CLK and mode signal SM are used as operation signals of the latch circuit 16. In a scan test in the LSSD method, the clock signal CLK, scan clock signal ACLK, and scan clock signal BCLK are used as operation signals of the latch circuit 16. The clock signal CLK, scan clock signal ACLK, and mode signal SM will be used below as positive logic signals (+CLK, +ACLK, and +SM), and the scan clock signal BCLK will be used below as a negative logic signal (−BCLK).

Referring again to FIG. 2, the latch control part or controller 22 has input terminals CK, ACK, BCK, and MS. The latch circuit 16 uses the input terminal CK to receive the clock signal +CLK and the input terminal MS to receive the mode signal +SM. The latch circuit 16 also uses the input terminal ACK to receive the scan clock signal +ACLK and the input terminal BCK to receive the scan clock signal −BCLK. The input terminals CK, ACK, BCK, and MS in the first embodiment function as a first input terminal and a second input terminal.

The latch control part 22 creates the operation control signals C1, C2, and C3 from the clock signal +CLK, mode signal +SM, scan clock signal +ACLK, and scan clock signal −BCLK that the latch control part 22 has received, the operation control signals C1, C2, and C3 being used as control signals to control the data latching part 20. The latch control part 22 outputs the operation control signals C1 to C3 to the data latching part 20 to control its operation.

As illustrated in FIG. 4, the latch control part 22 includes inverter circuits 36A, 36B, 36C, and 36D. The inverter circuit 36A outputs a clock signal −CLK corresponding to the clock signal +CLK. The inverter circuit 36B outputs a mode signal-SM corresponding to the mode signal +SM. The inverter circuit 36C outputs a scan clock signal −ACLK corresponding to the scan clock signal +ACLK. The inverter circuit 36D outputs a scan clock signal +BCLK corresponding to the scan clock signal −BCLK.

The latch control part 22 also includes a logic circuit 38, which creates the operation control signal C1 (+C1, −C1), a logic circuit 40, which creates the operation control signal C2 (+C2, −C2), and a logic circuit 42, which creates the operation control signal C3 (+C3, −C3).

The logic circuit 38 includes a negative AND (NAND) circuit 38A and an inverter circuit 38B to create the operation control signals +C1 and −C1 from the clock signal +CLK and mode signal −SM and outputs the created signals. The logic circuit 38 creates the operation control signal −C1 as, for example, −CLK/+SM and creates +C1 as, for example, +CLK&−SM. In the descriptions below, a logical sum is indicated by a slash (/) and a logical product is indicated by an ampersand (&).

The logic circuit 40 includes NAND circuits 40A and 40B and an inverter circuit 40C to create the operation control signals +C2 and −C2 from the clock signal +CLK, scan clock signal −ACLK, and mode signal +SM and outputs the created signals. The logic circuit 40 creates the operation control signal +C2 as, for example, +ACLK/(+CLK&+SM) and creates −C2 as, for example, −ACLK/(−CLK&−SM).

The logic circuit 42 includes an NAND circuit 42A and an inverter circuit 42B to create the operation control signals +C3 and −C3 from the clock signal −CLK and scan clock signal +BCLK and outputs the created signals. The logic circuit 42 creates the operation control signal −C3 as, for example, +CLK/−BCLK and creates +C3 as, for example, −CLK&+BCLK.

Referring again to FIG. 1, each of the plurality of latch circuits 16 in the scan test circuit 12 is connected to the scan control part 18. The scan control part 18 outputs control signals in the MUX-D method or LSSD method. Each latch circuit 16 in the scan test circuit 12 is controlled so as to operate in the LSSD method or MUX-D method according to a control signal received from the scan control part 18.

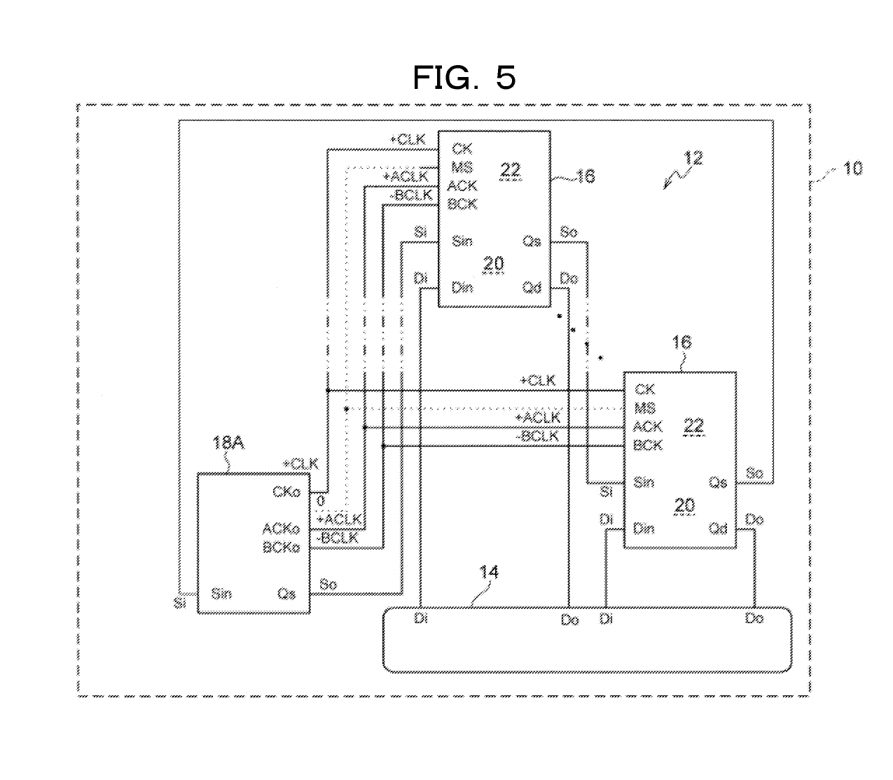

FIG. 5 illustrates an example in which the latch circuit 16 is controlled in the LSSD method. A scan control part 18A used as the scan control part 18 executes a scan test in the LSSD method. The scan control part 18A outputs the clock signal +CLK, scan clock signal +ACLK, and scan clock signal −BCLK as operation signals.

The scan control part 18A has an output terminal CKo, from which the clock signal +CLK is output, an output terminal ACKo, from which the scan clock signal +ACLK is output, and an output terminal BCKo, from which the scan control signal −BCLK is output.

The scan control part 18A also has an input terminal Sin and an output terminal Qs as an example. The output terminal Qs of the scan control part 18A is connected to, for example, the input terminal Sin of the latch circuit 16 at the foremost stage of the scan chain, and the input terminal Sin of the scan control part 18A is connected to, for example, the output terminal Qs of the latch circuit 16 at the last stage of the scan chain.

Thus, in the scan test circuit 12, the scan data So output from the scan control part 18A is sequentially transmitted among the plurality of latch circuits 16 and is finally returned to the scan control part 18A. To input the scan data Si to the scan test circuit 12 and to acquire the scan data So from the scan test circuit 12, a test apparatus connected to the semiconductor integrated circuit 10 may be used instead of the scan control part 18A.

The input terminal CK of each latch circuit 16 is connected to the output terminal CKo of the scan control part 18A. The input terminal ACK of each latch circuit 16 is connected to the output terminal ACKo of the scan control part 18A. The input terminal BCK of each latch circuit 16 is connected to the output terminal BCKo of the scan control part 18A.

If the latch circuit 16 is controlled in the LSSD method, the input terminal MS for the mode signal +SM is held at the L level (+SM=0). The L level of the input terminal MS in the first embodiment is assumed to be input to the input terminal MS as a prescribed value. As an example of a method of holding the input terminal MS of the latch circuit 16 at the L level, the scan control part 18A may have a terminal to which to output a L-level signal and the terminal may be connected to the input terminal MS of the latch circuit 16. However, the method of holding the input terminal MS at the L level is not limited to this; any other method may be used.

Thus, the input terminal MS of the latch circuit 16 is held at the L level and receives the clock signal +CLK and scan clock signals +ACLK and −BCLK output from the scan control part 18A.

Next, the operation of the latch circuit 16 connected to the scan control part 18A to which the LSSD method is applied will be described.

When connected to the scan control part 18A, the latch control part 22 in the latch circuit 16 controls the operation of the data latching part 20 according to the clock signal +CLK, scan clock signal +ACLK, and scan clock signal −BCLK.

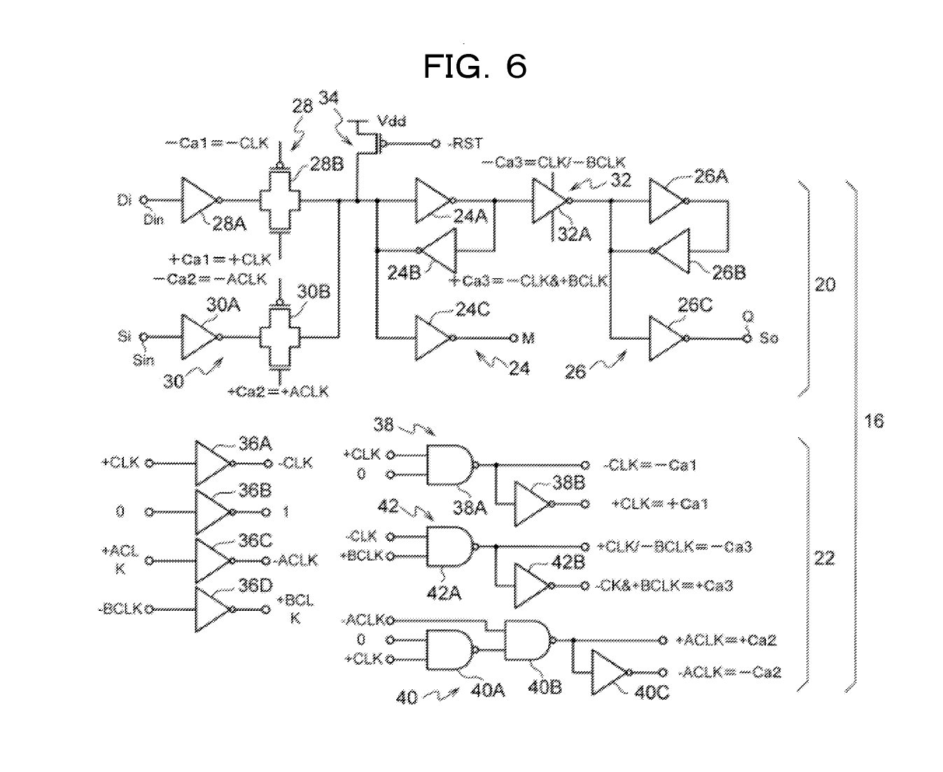

As illustrated in FIG. 6, the clock signal +CLK, scan clock signal +ACLK, and scan clock signal −BCLK are input to the latch control part 22 with the mode signal +SM held at the L level (+SM=0). As the operation control signals C1 to C3, the latch control part 22 outputs operation control signals Ca1 to Ca3 according to the clock signal +CLK, mode signal +SM, and scan clock signals +ACLK and −BCLK. The operation control signal Ca1 (+Ca1, −Ca1) in the first embodiment functions as one of the first operation control signal and fourth operation control signal. The operation control signal Ca2 (+Ca2, −Ca2) in the first embodiment functions as one of the second operation control signal and fifth operation control signal. The operation control signal Ca3 (+Ca3, −Ca3) in the first embodiment functions as one of the third operation control signal and sixth operation control signal.

In the latch control part 22, the operation control signals +Ca1 and −Ca1 output from the logic circuit 38 respectively become +CLK and −CLK. In the latch control part 22, the operation control signals +Ca2 and −Ca2 output from the logic circuit 40 respectively become +ACLK and −ACLK. In the latch control part 22, the operation control signals +Ca3 and −Ca3 output from the logic circuit 42 respectively become +CLK/−BCLK and −CLK&+BCLK.

In the latch circuit 16, when the scan clock signal +ACLK becomes the H level (+ACLK=1), the operation control signal +Ca2 becomes 1 and the operation control signal −Ca2 becomes 0. In the data latching part 20, after the operation control signal +Ca2 has become 1 and the operation control signal −Ca2 has become 0, the TG 30B is turned on, retrieving scan data Si from the input terminal Sin and latching the retrieved scan data Si in the first latch part 24.

In the latch circuit 16, when the clock signal −CLK becomes the H level (−CLK=1) and the scan clock signal +BCLK becomes the H level (+BCLK=1), the operation control signal +Ca3 becomes the H level (+Ca3=1, −Ca3=0). In the data latching part 20, after the operation control signal +Ca3 has become 1 and the operation control signal −Ca3 has become 0, the clocked inverter circuit 32A is turned on, retrieving the scan data Si from the first latch part 24 and latching the retrieved scan data Si in the second latch part 26.

In the latch circuit 16, after the scan data Si has been latched in the second latch part 26 in the data latching part 20, the scan data Si is output from the output terminal Qs as scan data So.

If the mode signal +SM is set to a prescribed value (fixed value), the latch circuit 16 latches the scan data Si and outputs the scan data So, according to the clock signal +CLK and scan clock signals +ACLK and −BCLK, to which the LSSD method is applied. The latch circuit 16 also latches data Di output from the combinational logic circuit 14 and outputs data Do.

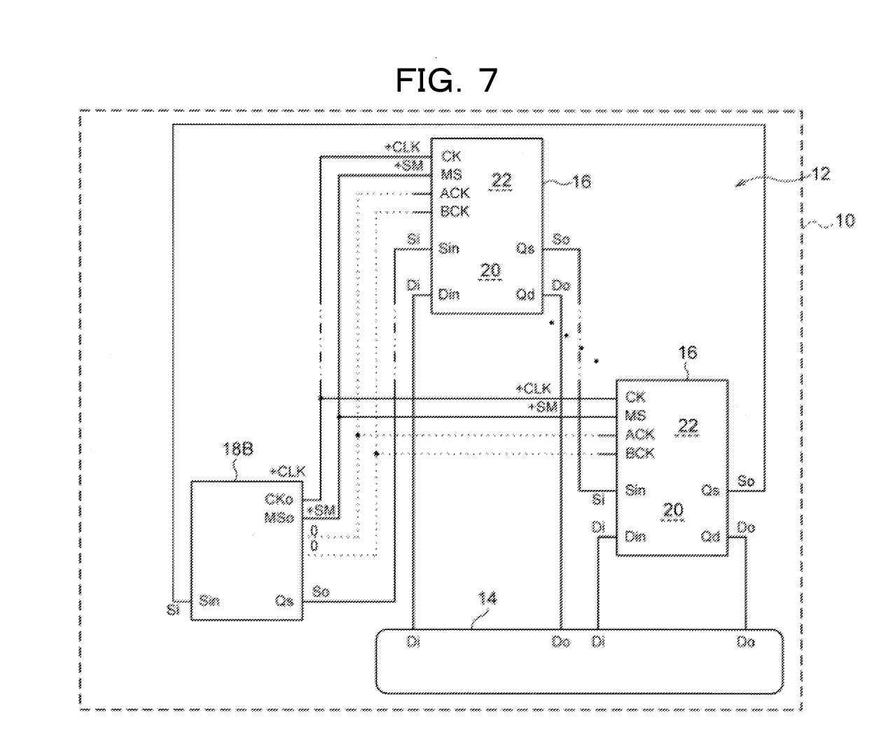

FIG. 7 illustrates an example in which the latch circuit 16 is controlled in the MUX-D method. A scan control part 18B used as the scan control part 18 has an output terminal CKo from which the clock signal +CLK is output and an output terminal MSo from which the mode signal +SM is output. The scan control part 18B outputs the clock signal +CLK and mode signal +SM as operation signals of the latch circuit 16 to execute a scan test in the MUX-D method.

In each latch circuit 16, the input terminal CK is connected to the output terminal CKo of the scan control part 18B and the input terminal MS is connected to the output terminal MSo of the scan control part 18B. In the latch circuit 16, the input terminal ACK for the scan clock signal +ACLK is held at the L level (+ACLK=0), and the scan clock signal −BCLK is also held at the L level (−BCLK=0). The L level of the input terminals ACK and BCK in the first embodiment is assumed to function to input a prescribed value to the input terminals ACK and BCK.

The output terminal Qs of the scan control part 18B is connected to, for example, the input terminal Sin of the latch circuit 16 at the foremost stage of the scan chain, and the Sin of the scan control part 18B is connected to, for example, the output terminal Qs of the latch circuit 16 at the last stage of the scan chain.

Next, the operation of the latch circuit 16 connected to the scan control part 18B to which the MUX-D method is applied will be described.

When connected to the scan control part 18B, the latch control part 22 in the latch circuit 16 controls the operation of the data latching part 20 according to the clock signal +CLK and mode signal +SM.

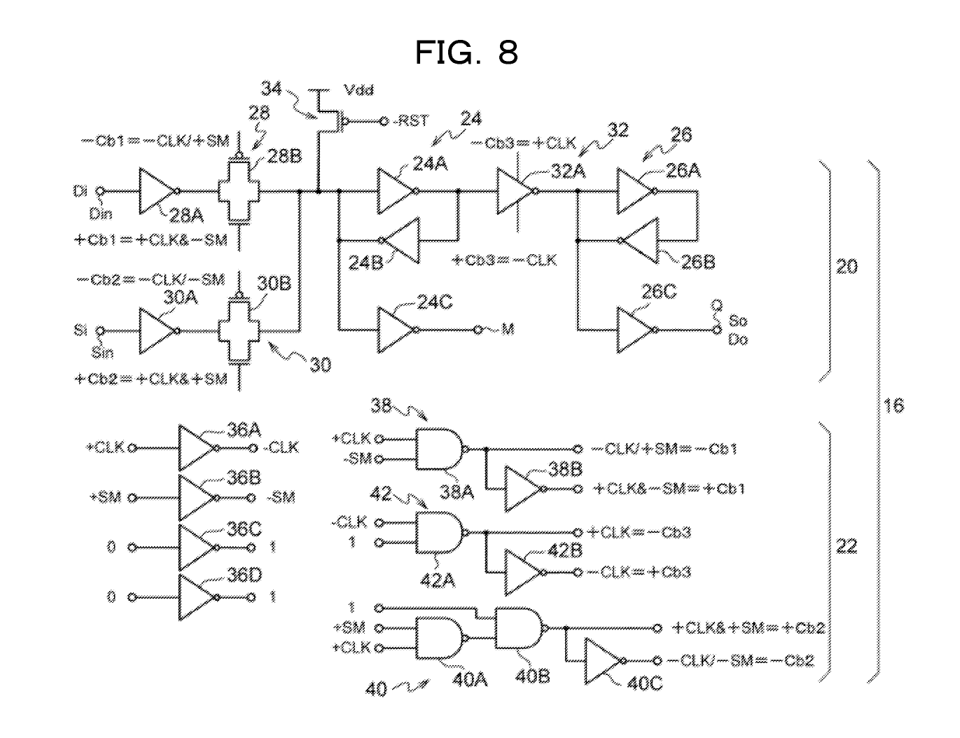

As illustrated in FIG. 8, the clock signal +CLK and mode signal +SM are input to the latch control part 22 with the scan clock signals +ACLK and −BCLK held at the L level (+ACLK=0, −BCLK=0). As the operation control signals C1 to C3, the latch control part 22 outputs operation control signals Cb1 to Cb3 according to the clock signal +CLK, mode signal +SM, and scan clock signals +ACLK and −BCLK. In contrast to Ca1 described above, the operation control signal Cb1 (+Cb1, −Cb1) in the first embodiment functions as the other of the first operation control signal and fourth operation control signal. In contrast to Cat described above, the operation control signal Cb2 (+Cb2, −Cb2) in the first embodiment functions as the other of the second operation control signal and fifth operation control signal. In contrast to Ca3 described above, the operation control signal Cb3 (+Cb3, −Cb3) in the first embodiment functions as the other of the third operation control signal and sixth operation control signal.

In the latch control part 22, the operation control signals +Cb1 and −Cb1 output from the logic circuit 38 respectively become +CLK&−SM and −CLK/+SM. In the latch control part 22, the operation control signals +Cb2 and −Cb2 output from the logic circuit 40 respectively become +CLK&+SM and −CLK/−SM. In the latch control part 22, the operation control signals +Cb3 and −Cb3 output from the logic circuit 42 respectively become −CLK and +CLK.

In the latch circuit 16, when the clock signal +CLK becomes the H level (+CLK=1) and the mode signal +SM becomes the L level (the mode signal −SM becomes the H level), the operation control signal +Cb1 becomes 1 and the operation control signal −Cb1 becomes 0. In the data latching part 20, after the operation control signal +Cb1 has become 1 and the operation control signal −Cb1 has become 0, the TG 28B is turned on, retrieving scan data Di from the input terminal Din and latching the retrieved scan data Di in the first latch part 24.

When, in the latch control part 22, the clock signal +CLK then becomes the L level (the clock signal −CLK becomes the H level), the operation control signal +Cb3 becomes 1 and the operation control signal −Cb3 becomes 0. In the data latching part 20, after the operation control signal +Cb3 has become 1 and the operation control signal −Cb3 has become 0, the clocked inverter circuit 32A is turned on, retrieving the data Di from the first latch part 24 and latching the retrieved data Di in the second latch part 26. The latch circuit 16 outputs the data Di latched in the second latch part 26 in the data latching part 20 from the output terminal Qd as data Do.

In the latch circuit 16, when the clock signal +CLK becomes the H level (+CLK=1) and the mode signal +SM becomes the H level, the operation control signal +Cb2 becomes 1 and the operation control signal −Cb2 becomes 0. In the data latching part 20, after the operation control signal +Cb2 has become 1 and operation control signal −Cb2 has become 0, the TG 30B is turned on, retrieving the scan data Si from the input terminal Sin and latching the retrieved data Si in the first latch part 24.

When, in the scan control part 18B, the clock signal +CLK then becomes the L level (the clock signal −CLK becomes the H level), the operation control signal +Cb3 becomes 1 and the operation control signal −Cb3 becomes 0. In the data latching part 20, after the operation control signal +Cb3 has become 1 and the operation control signal −Cb3 has become 0, the clocked inverter circuit 32A is turned on, retrieving the data Si from the first latch part 24 and latching the retrieved data Si in the second latch part 26. The latch circuit 16 outputs the data Si latched in the second latch part 26 in the data latching part 20 from the output terminal Qs as scan data So.

As described above, if the scan clock signals +ACLK and −BCLK are set to their prescribed values, the latch circuit 16 latches scan data Si and outputs scan data So, according to the clock signal +CLK and mode signal +SM, to which the MUX-D method is applied. The latch circuit 16 also latches data Di output from the combinational logic circuit 14 and outputs data Do.

That is, the latch circuit 16 operates accurately according to the clock signal CLK, scan clock signal, ACLK, and scan clock signal BCLK, to which the LSSD method is applied. The latch circuit 16 also operates accurately according to the clock signal CLK and mode signal SM, to which the MUX-D method is applied.

Accordingly, if the latch circuit 16 is used in the circuit design of the semiconductor integrated circuit 10 as a single circuit block, the semiconductor integrated circuit 10 can be more efficiently designed.

If the latch circuit 16 is combined with a latch circuit to which the MUX-D method is applied or a latch circuit to which the LSSD method is applied, a scan chain can be formed as described below.

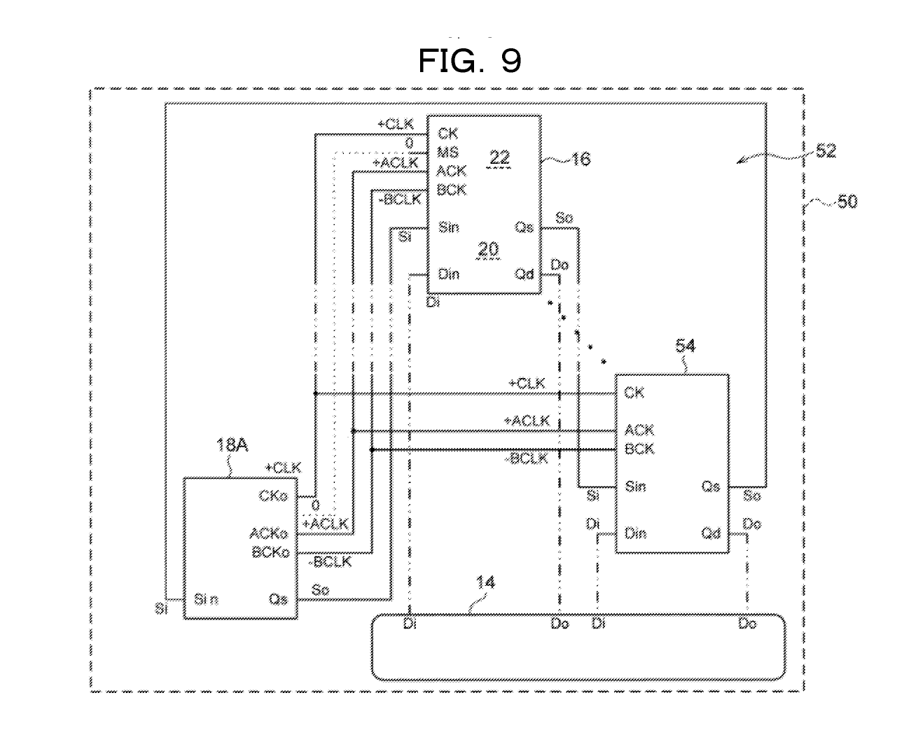

FIG. 9 illustrates a semiconductor integrated circuit 50. A scan test circuit 52 is formed in the semiconductor integrated circuit 50. The scan test circuit 52 includes latch circuits 16 and a latch circuit 54 that operates in the LSSD method. The scan test circuit 52 in the semiconductor integrated circuit 50 is used instead of the scan test circuit 12 in the semiconductor integrated circuit 10. Alternatively, in the scan test circuit 52 in the semiconductor integrated circuit 50, the latch circuit 54 is used instead of part the latch circuit 16 in the scan test circuit 12.

The latch circuit 54 has an input terminal Din and an output terminal Qd. The input terminals Din of the latch circuits 16 and 54 are connected to the combinational logic circuit 14. Data Di output from the combinational logic circuit 14 is input to the input terminal Din. The output terminals Qd of the latch circuits 16 and 54 are connected to the combinational logic circuit 14. Data Do is output from the output terminal Qd to the combinational logic circuit 14.

The latch circuit 54 has input terminals CK, ACK, and BCK. The latch circuit 54 operates according to the clock signal +CLK input to the input terminal CK, the scan clock signals +ACLK input to the input terminal ACK, and the scan clock signal −BCLK input to the input terminal BCK. The latch circuit 54 latches scan data Si in a master latch in synchronization with the scan clock signal +ACLK. A slave latch in the latch circuit 54 latches scan data Si in the master latch in synchronization with the scan clock signal −BCLK and outputs the latched scan data Si as scan data So. Accordingly, the latch circuit 54 functions as a data latching part that operates according to control signals in the LSSD method.

In the scan test circuit 52, a scan chain is formed with a plurality of latch circuits 16 and the latch circuit 54. The latch circuit 54 has an input terminal Sin and an output terminal Qs. The input terminal Sin of a latch circuit 16 is connected to the output terminal Qs of the latch circuit 16 at the previous stage or the latch circuit 54 (if disposed at the previous stage), and the output terminal Qs of that latch circuit 16 is connected to the input terminal Sin of the latch circuit 16 at the next stage or the latch circuit 54 (if disposed at the next stage). The latch circuit 54 is similarly connected to the latch circuits 16 at the previous stage and next stage.

The semiconductor integrated circuit 50 includes a scan control part 18A to which the LSSD method is applied. The output terminal Qs of the scan control part 18A is connected to the input terminal Sin of the latch circuit 16 or latch circuit 54 at the foremost stage (in FIG. 9, a latch circuit 16 is disposed at the foremost stage as an example). The input terminal Sin of the scan control part 18A is connected to the output terminal Qs of the latch circuit 16 or latch circuit 54 at the last stage (in FIG. 9, the latch circuit 54 is disposed at the last stage as an example).

In the scan test circuit 52, the input terminals CK of each latch circuit 16 and the latch circuit 54 are connected to the output terminal CKo of the scan control part 18A. The input terminals ACK of each latch circuit 16 and the latch circuit 54 are connected to the output terminal ACKo of the scan control part 18A, and their input terminals BCK are connected to the output terminal BCKo of the scan control part 18A. The scan test circuit 52 is set so that a logic-0 (L-level) signal is input to the input terminal MS of each latch circuit 16.

Thus, each latch circuit 16 and the latch circuit 54 operate according to the clock signal +CLK, scan clock signal +ACLK, and scan clock signal −BCLK that are input from the scan control part 18A.

Therefore, when a scan chain is formed by the latch circuits 16 and the latch circuit 54 that operates in the LSSD method, the latch circuits 16 can be used in a scan test in the LSSD method.

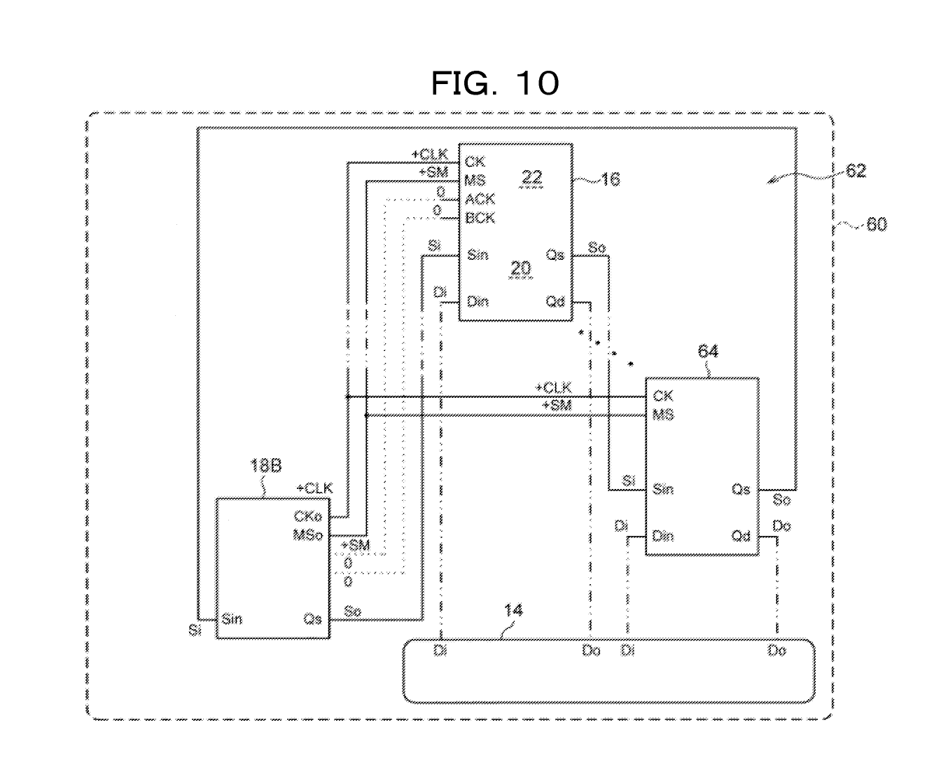

FIG. 10 illustrates a semiconductor integrated circuit 60. A scan test circuit 62 is formed in the semiconductor integrated circuit 60. The scan test circuit 62 includes latch circuits 16 and a latch circuit 64 that operates in the MUX-D method. The scan test circuit 62 in the semiconductor integrated circuit 60 is used instead of the scan test circuit 12 in the semiconductor integrated circuit 10. Alternatively, in the scan test circuit 62 in the semiconductor integrated circuit 60, the latch circuit 64 is used instead of part the latch circuit 16 in the scan test circuit 12.

The latch circuit 64 has an input terminal Din to which data Di is input from the combinational logic circuit 14 and an output terminal Qd from which data Do is output. The latch circuit 64 also has an input terminal Sin to which scan data Si is input and an output terminal Qs from which scan data So is output. The latch circuit 64 further has an input terminal CK to which the clock signal +CLK is input and an input terminal MS to which the mode signal +SM is input. The latch circuit 64 operates in synchronization with the clock signal +CLK input to the input terminal CK and latches data Di or scan data Si according to the mode signal +SM. Accordingly, the latch circuit 64 functions as a data latching part that operates according to control signals in the MUX-D method.

In the scan test circuit 62, a scan chain is formed with a plurality of latch circuits 16 and the latch circuit 64. The latch circuit 64 has an input terminal Sin and an output terminal Qs. The input terminal Sin of a latch circuit 16 is connected to the output terminal Qs of the latch circuit 16 at the previous stage or the latch circuit 64 (if disposed at the previous stage), and the output terminal Qs of that latch circuit 16 is connected to the input terminal Sin of the latch circuit 16 at the next stage or the latch circuit 54 (if disposed at the next stage). The latch circuit 64 is similarly connected to the latch circuits 16 at the previous stage and next stage.

The semiconductor integrated circuit 60 includes a scan control part 18B to which the MUX-D method is applied. The output terminal Qs of the scan control part 18B is connected to the input terminal Sin of the latch circuit 16 or latch circuit 64 at the foremost stage (in FIG. 10, a latch circuit 16 is disposed at the foremost stage as an example). The input terminal Sin of the scan control part 18B is connected to the output terminal Qs of the latch circuit 16 or latch circuit 64 at the last stage (in FIG. 10, the latch circuit 64 is disposed at the last stage as an example).

In the scan test circuit 62, the input terminals CK of each latch circuits 16 and the latch circuit 64 are connected to the output terminal CKo of the scan control part 18B. The input terminals MS of each latch circuit 16 and the latch circuit 64 are connected to the output terminal MSo of the scan control part 18B. The scan test circuit 62 is set so that logic-0 (L-level) signals (logic-0 scan clock signal +ACLK and logic-0 scan clock signal −BCLK) are respectively input to the input terminals ACK and BCK of the latch circuit 16.

Thus, each latch circuit 16 and the latch circuit 64 operate according to the clock signal +CLK and mode signal +SM that are input from the scan control part 18B. For example, each latch circuit 16 and the latch circuit 64 operate in synchronization with the clock signal +CLK and latch data Di or scan data Si according to the mode signal +SM. After having latched the data Di, the latch circuit 16 and latch circuit 64 output the latched Di from the output terminal Qd as data Do at a timing at which they retrieve next data Di. After having latched the data Si, the latch circuit 16 and latch circuit 64 output the latched Si from the output terminal Qs as data So at a timing at which they retrieve next scan data Si.

Therefore, when a scan chain is formed by the latch circuits 16 and the latch circuit 64 that operates in the MUX-D method, the latch circuits 16 can be used in a scan test in the MUX-D method.

### Second Embodiment

Next, a second embodiment will be described. In the second embodiment, functional parts that are the same as in the first embodiment will be given the same reference characters as in the first embodiment and repeated descriptions will be omitted.

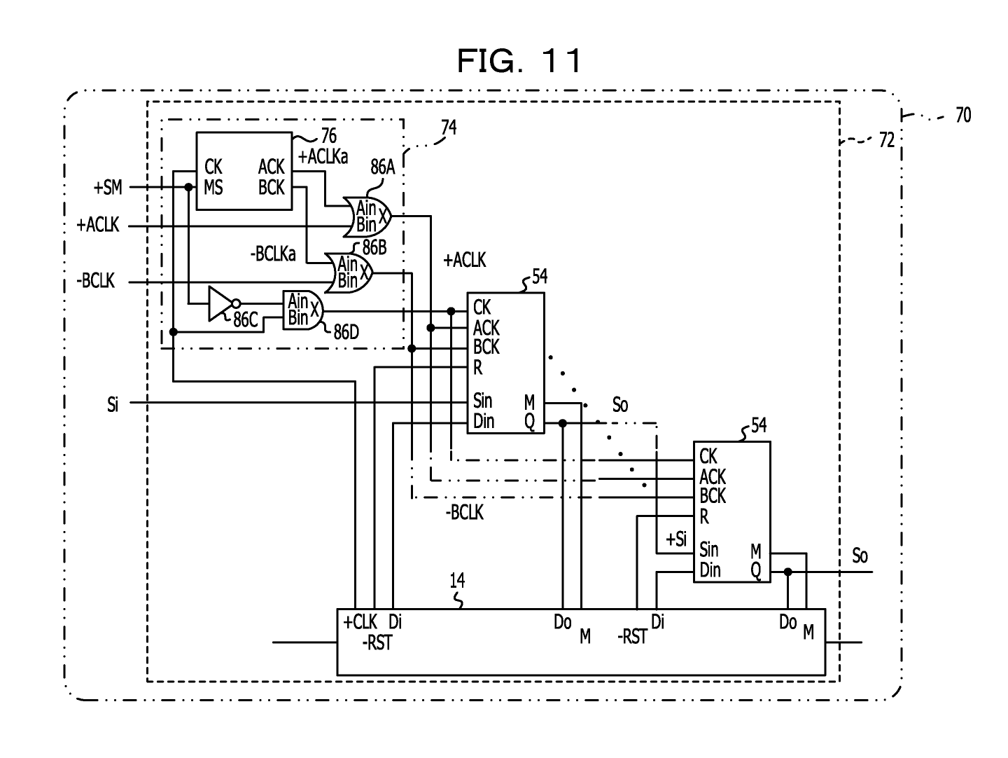

FIG. 11 illustrates a semiconductor integrated circuit 70 in the second embodiment. The semiconductor integrated circuit 70 in the second embodiment functions as an example of a semiconductor integrated circuit. A scan test circuit 72 is formed in the semiconductor integrated circuit 70. A plurality of latch circuits 54 are also formed in the scan test circuit 72, forming a scan chain.

Each latch circuit 54 has an input terminals Din and Sin and an output terminal Q. The latch circuit 54 also has an output terminal M from which data Mo latched in a master latch is output. The input terminal Din of the latch circuit 54 and its output terminals Q and M are connected to the combinational logic circuit 14. Thus, the latch circuit 54 receives, through the input terminal Din, data Di output from the combinational logic circuit 14, outputs data Do from the output terminal Q to the combinational logic circuit 14, and outputs data Mo from the output terminal M to the combinational logic circuit 14.

The latch circuit 54 operates in the LSSD method according to the clock signal +CLK input to the input terminal CK of the latch circuit 54, the scan clock signal +ACLK input to the input terminal ACK of the latch circuit 54, and the scan clock signal −BCLK input to the input terminal BCLK of the latch circuit 54. The latch circuit 54 in the second embodiment functions as a data latching part.

The input terminal R of the latch circuit 54 is connected to the combinational logic circuit 14, so data in the latch circuit 54 is initialized by a reset signal −RST received from the combinational logic circuit 14. As an example in the second embodiment, the input terminal CK of the latch circuit 54 is connected to the combinational logic circuit 14 and the latch circuit 54 operates in synchronization with the clock signal +CLK output from the combinational logic circuit 14.

The scan test circuit 72 includes a latch control part 74. The latch control part 74 may be provided in each latch circuit 54. Alternatively, one latch control part 74 may be shared among a plurality of latch circuits 54. The latch control part 74 in the second embodiment operates as a latch control part. The latch circuit 54 and latch control part 74 in the second embodiment function as a latch circuit.

The latch control part 74 includes a signal creating part 76. The signal creating part 76 includes an input terminal CK and an input terminal MS. The signal creating part 76 also includes output terminals ACKo and BCKo. The input terminal CK of the signal creating part 76, for example, is connected to the combinational logic circuit 14 and receives the clock signal +CLK from the combinational logic circuit 14. To operate the latch circuit 54 in the MUX-D method, the mode signal +SM is input to the input terminal MS of the signal creating part 76.

The signal creating part 76 receives the clock signal +CLK and mode signal +SM and creates a scan clock signal +ACLKa and a scan clock signal −BCLKa from the received clock signal +CLK and mode signal +SM. The signal creating part 76 outputs the scan clock signal +ACLKa from the output terminal ACKo and the scan clock signal −BCLKa from the output terminal BCKo. The scan clock signals +ACLKa and −BCLKa in the second embodiment function as one of a first control signal and a second control signal.

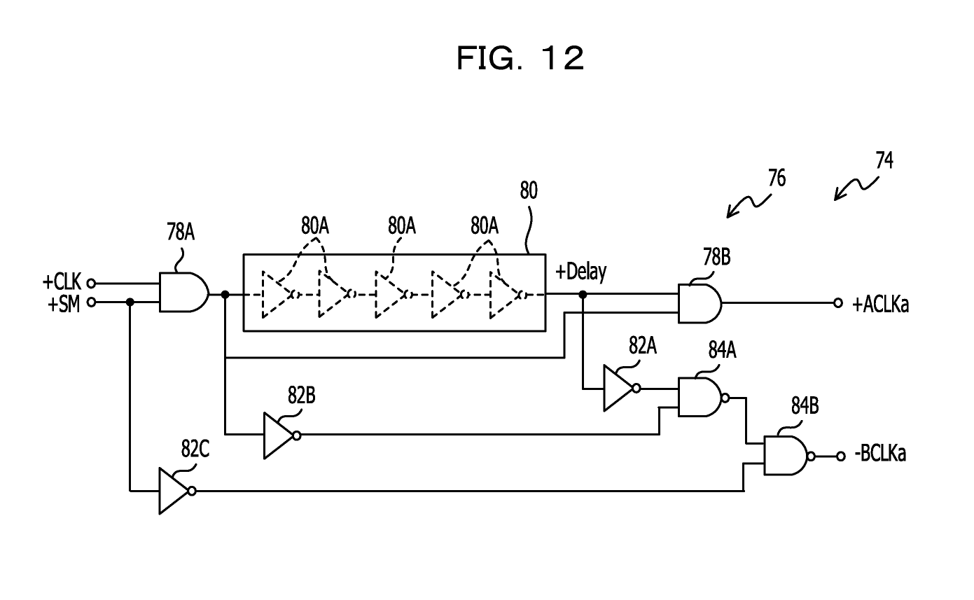

FIG. 12 illustrates an example of the signal creating part 76. The signal creating part 76 includes AND circuits 78A and 78B and a delay circuit 80. The AND circuit 78A receives the clock signal +CLK and mode signal +SM. The AND circuit 78A then takes the logical product of the clock signal +CLK and mode signal +SM and outputs the logical product.

The delay circuit 80 receives the signal output from the AND circuit 78A. The delay circuit 80 is formed by, for example, connecting a plurality of inverter circuits 80A in series. The delay circuit 80 delays a signal that it has received by a preset time Δt, inverts the delayed signal, and outputs the resulting signal as a delay signal +Delay. The time Δt, which is preset in the delay circuit 80, is determined according to the cycle of the clock signal +CLK so that the time durations (time durations of the H levels) of the scan clock signals +ACLKa and +BCLKa differ from each other.

The AND circuit 78B receives the signal output from the AND circuit 78A and the delay signal +Delay output from the delay circuit 80. The AND circuit 78B takes the logical product of the output signal from the AND circuit 78A and the delay signal +Delay and outputs the logical product as the scan clock signal +ACLKa.

The signal creating part 76 also includes inverter circuits 82A, 82B and 82C and NAND circuits 84A and 84B. The NAND circuit 84A receives the delay signal +Delay output from the delay circuit 80 through the inverter circuit 82A. The NAND circuit 84A also receives the signal output from the AND circuit 78A through the inverter circuit 82B. The NAND circuit 84B receives the signal output from the NAND circuit 84A and also receives the mode signal +SM through the inverter circuit 82C. The NAND circuit 84B creates the scan clock signal +BCLKa from the clock signal +CLK, mode signal +SM, and delay signal +Delay. The NAND circuit 84B inverts the scan clock signal +BCLKa and outputs a resulting scan clock signal −BCLKa.

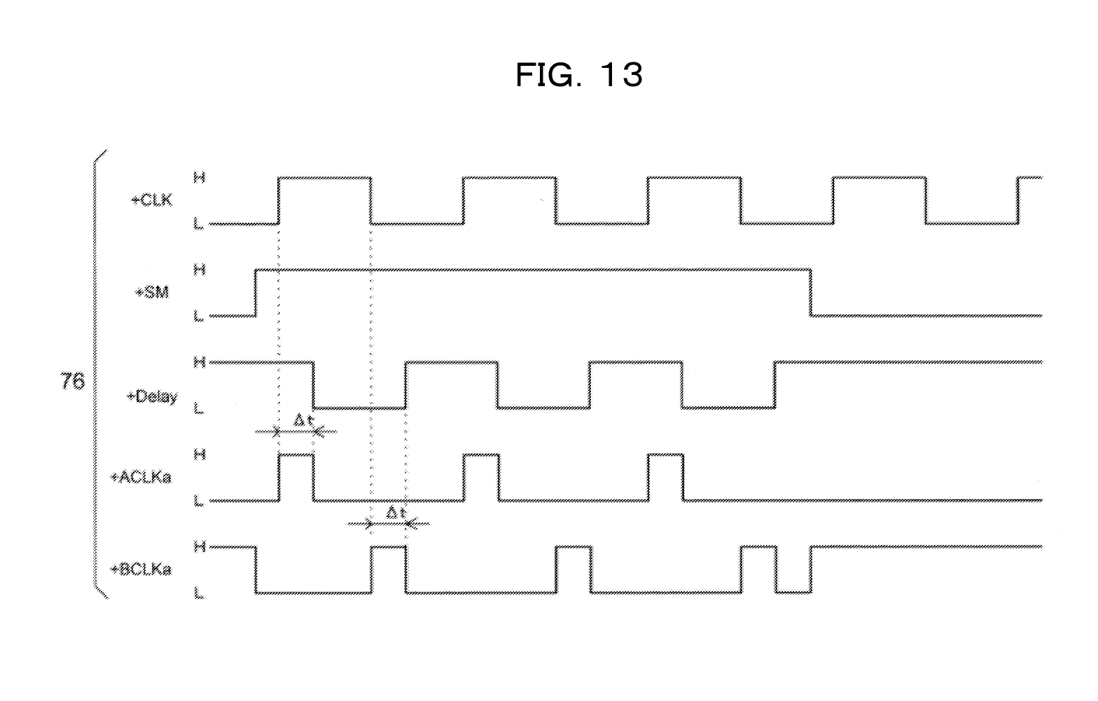

FIG. 13 is a schematic timing diagram of the clock signal +CLK, mode signal +SM, delay signal +Delay, scan clock signal +ACLKa, and scan clock signal +BCLKa in the signal creating part 76.

In the signal creating part 76, when the clock signal +CLK and mode signal +SM become the H level (shift mode), the delay signal +Delay becomes the L level the time Δt after the clock signal +CLK has become the L level. The scan clock signal +ACLKa output from the AND circuit 78B becomes the H level when the clock signal +CLK, mode signal +SM, and delay signal +Delay become the H level. The scan clock signal +ACLKa output from the AND circuit 78B changes from the H level to the L level when the delay signal +Delay becomes the L level. Accordingly, the scan clock signal +ACLKa is created in synchronization with the rising edge of the clock signal +CLK.

In the signal creating part 76, when the clock signal +CLK becomes the L level with the mode signal +SM at the H level, the delay signal +Delay becomes the H level the time Δt after the clock signal +CLK has become the H level. When the clock signal +CLK become the H level, the scan clock signal +BCLKa output from the NAND circuit 84B becomes the L level. The scan clock signal +BCLKa output from the NAND circuit 84B changes to the H level when the clock signal +CLK becomes the L level, and changes from the H level to the L level when the delay signal +Delay becomes the H level. Accordingly, the scan clock signal +BCLKa is created in synchronization with the falling edge of the clock signal +CLK. When the mode signal +SM changes from the H level to the L level, the signal creating part 76 holds the scan clock signals +ACLKa and +BCLKa at prescribed values (+ACLKa=0, +BCLKa=1).

Referring again to FIG. 11, the latch control part 74 includes OR circuits 86A and 86B, an inverter circuit 86C, and an AND circuit 86D. The OR circuit 86A receives the scan clock signal +ACLKa output from the signal creating part 76 at the input terminal Ain of the OR circuit 86A. The OR circuit 86A also receives the scan clock signal +ACLK, which is used to operate the scan test circuit 72 in the LSSD method, at the input terminal Bin of the OR circuit 86A. The output terminal X of the OR circuit 86A is connected to the input terminal ACK of each latch circuit 54.

The OR circuit 86B receives the scan clock signal −BCLKa output from the signal creating part 76 at the input terminal Ain of the OR circuit 86B. The OR circuit 86B also receives the scan clock signal −BCLK, which is used to operate the scan test circuit 72 in the LSSD method, at the input terminal Bin of the OR circuit 86B. The output terminal X of the OR circuit 86B is connected to the input terminal BCK of each latch circuit 54.

The inverter circuit 86C receives mode signal +SM. The AND circuit 86D receives the inverted signal of the mode signal +SM, the inverted signal being output from the inverter circuit 86C, at the input terminal Ain of the AND circuit 86D and also receives clock signal +CLK output from the combinational logic circuit 14 at the input terminal Bin of the AND circuit 86D. The output terminal X of the AND circuit 86D is connected to the input terminal CK of the latch circuit 54.

The signal creating part 76 in the latch control part 74 outputs the scan clock signal +ACLKa to the OR circuit 86A and also output the scan clock signal −BCLKa to the OR circuit 86B, according to the mode signal +SM input to the signal creating part 76. If the mode signal +SM becomes the L level (capture mode), the scan clock signals +ACLKa and −BCLKa to be output from the signal creating part 76 are stopped in the latch control part 74.

If the scan test circuit 72 is to be operated in the MUX-D method, the input terminal Bin of the OR circuit 86A in the latch control part 74 is held at the L level to set the scan clock signal +ACLK received at the input terminal Bin of the OR circuit 86A to a prescribed value (+ACLK=0). If the scan test circuit 72 is to be operated in the MUX-D method, the input terminal Bin of the OR circuit 86B in the latch control part 74 is held at the L level to set the scan clock signal −BCLK received at the input terminal Bin of the OR circuit 86B to a prescribed value (−BCLK=0).

If the scan clock signal +ACLK is not input to the input terminal Bin of the OR circuit 86A and the input terminal Bin is thereby at the L level, the OR circuit 86A outputs the scan clock signal +ACLKa, which is received at the input terminal Ain from the signal creating part 76, to the latch circuit 54 as the scan clock signal +ACLK. If the scan clock signal −BCLK is not input to the input terminal Bin of the OR circuit 86B and the input terminal Bin is thereby at the L level, the OR circuit 86B outputs the scan clock signal −BCLKa, which is received at the input terminal Ain from the signal creating part 76, to the latch circuit 54 as the scan clock signal −BCLK.

When the mode signal +SM input to the latch control part 74 becomes the H level (shift mode), the output from the inverter circuit 86C becomes the L level and the AND circuit 86D stops the output of the clock signal +CLK to the latch circuit 54. When the mode signal +SM input to the latch control part 74 becomes the L level (capture mode), the output from the inverter circuit 86C becomes the H level and the AND circuit 86D outputs the clock signal +CLK to the latch circuit 54.

If the scan test circuit 72 is to be operated in the LSSD method, the input terminal MS of the signal creating part 76 in the latch control part 74 is held at the L level to fix the mode signal +SM input to the signal creating part 76.

If the mode signal +SM is not input to the input terminal SM of the signal creating part 76 in the latch control part 74 and the input terminal SM is thereby at the L level, the output terminals ACKo and BCKo of the signal creating part 76 become the L level (+ACLK=0, −BCLK=0). When the output terminals ACKo and BCKo become the L level, the input terminal Ain of the OR circuit 86A becomes the L level, the input terminal Ain of the OR circuit 86B becomes the L level, and the input terminal Ain of the AND circuit 86D becomes the H level.

If the input terminal Ain of the OR circuit 86A is at the L level, the OR circuit 86A outputs the scan clock signal +ACLK, which is received at the input terminal Bin, to the latch circuit 54. If the input terminal Ain of the OR circuit 86B in the latch control part 74 is at the L level, the OR circuit 86B outputs the scan clock signal −BCLK, which is received at the input terminal Bin, to the latch circuit 54. If the input terminal Ain of the AND circuit 86D is at the H level, the AND circuit 86D outputs the clock signal +CLK, which is received at the input terminal Bin, to the latch circuit 54.

As described above, the latch control part 74 outputs scan clock signals +ACLKa and −BCLKa to the latch circuit 54, regardless of whether the scan test method is the MUX-D method or LSSD method. If the scan test method is the LSSD method, the latch control part 74 outputs the clock signal +CLK to each latch circuit 54. If the scan test method is the MUX-D method, the latch control part 74 outputs the clock signal +CLK to each latch circuit 54 or stops the output of the clock signal +CLK to the latch circuit 54 according to whether mode signal +SM is at the L level or the H level. When the clock signal +CLK and the scan clock signals +ACLKa and −BCLKa, which are used to execute a scan test, are input to the latch circuit 54, it operates according to the clock signal +CLK and scan clock signals +ACLKa and −BCLKa that have been input to the latch circuit 54.

If the latch control part 74 is connected to the scan control part 18A, the scan test circuit 72 executes a scan test in the LSSD method. By contrast, if the latch control part 74 is connected to the scan control part 18B, the scan test circuit 72 executes a scan test in the MUX-D method.

Accordingly, the latch control part 74 controls each latch circuit 54 in the scan test circuit 72 so that the latch circuit 54 operates in the MUX-D method by setting the scan clock signals +ACLK and −BCLK applied to the LSSD method to prescribed values. The latch control part 74 also controls each latch circuit 54 in the scan test circuit 72 so that the latch circuit 54 operates in the LSSD method by setting the mode signal +SM applied to the MUX-D method to a prescribed value.

When the latch circuit 54 operating in the LSSD method is built into the semiconductor integrated circuit 70 together with the latch control part 74, it becomes possible to operate the latch circuit 54 in any one of the MUX-D method and LSSD method.

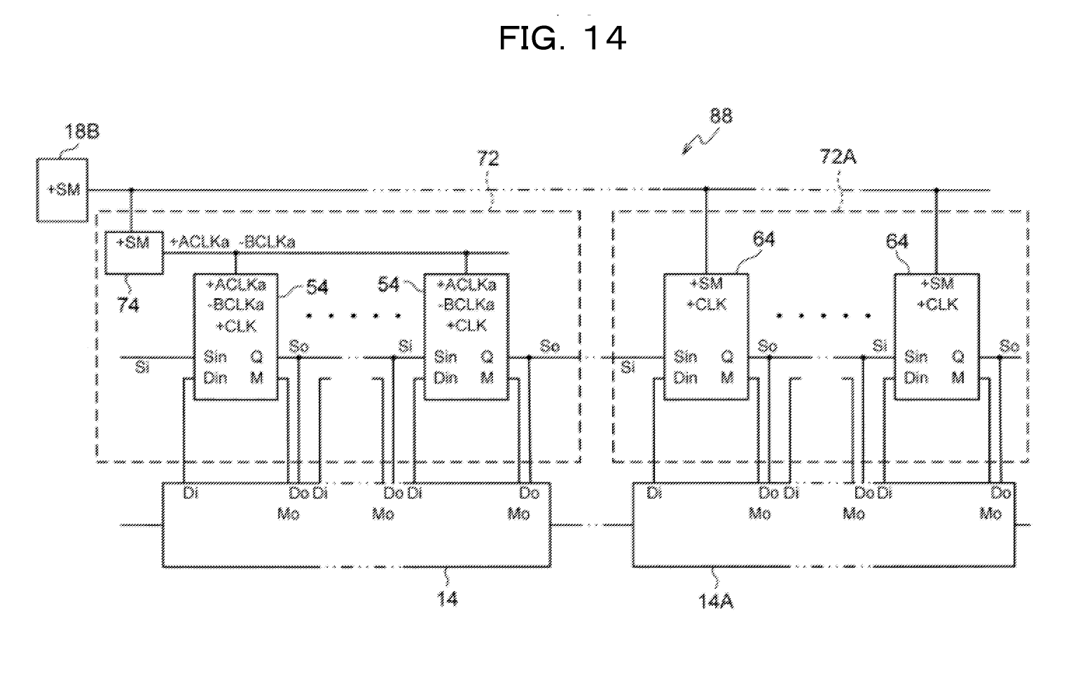

FIG. 14 illustrates a scan test circuit 88 in which latch circuits 54 and the latch control part 74 are used. The scan test circuit 88 includes the scan test circuit 72 and a scan test circuit 72A. In the scan test circuit 72A, a scan chain is formed by a plurality of latch circuits 64, each of which functions as a data latching part operating in the MUX-D method.

Each latch circuit 54 in the scan test circuit 72 is connected to the combinational logic circuit 14, and each latch circuit 64 in the scan test circuit 72A is connected to a combinational logic circuit 14A. In the scan test circuit 88, scan data So output from the latch circuit 54 at the last stage in the scan test circuit 72, for example, is input to the latch circuit 64 at the foremost stage in the scan test circuit 72A.

The scan test circuit 72 and scan test circuit 72A are connected to the scan control part 18B, which executes a scan test in the MUX-D method. The scan control part 18B outputs the mode signal +SM to each latch circuit 64 in the scan test circuit 72A. The operation of the latch circuit 64 is controlled by the mode signal +SM output from the scan control part 18B. Thus, in the scan test circuit 72A, the latch circuits 64 operate in the MUX-D method to execute a scan test.

In the scan test circuit 72, the latch control part 74 is connected to the scan control part 18B and each latch circuit 54 is connected to the latch control part 74. If the input terminal Bin of the OR circuit 86A is at the L level, the latch control part 74 holds the scan clock signal +ACLK input to the input terminal Bin of the OR circuit 86A at a prescribed value. If the input terminal Bin of the OR circuit 86B is at the L level, the latch control part 74 holds the scan clock signal −BCLK input to the input terminal Bin of the OR circuit 86B at a prescribed value.

The latch control part 74 creates the scan clock signals +ACLKa and −BCLKa from the clock signal +CLK and the mode signal +SM that is input from the scan control part 18B and outputs the created scan clock signals +ACLKa and −BCLKa to each latch circuit 54. The operation of the latch circuit 54 is controlled according to the clock signal +CLK and to the scan clock signals +ACLK (+ACLKa) and −BCLK (−BCLKa) input from the latch control part 74.

In the scan test circuit 88, since the latch control part 74 is provided for the latch circuits 54, which operate in the LSSD method, the scan test circuit 72 operates in the MUX-D method in the same way as with the scan test circuit 72A.

In the scan test circuit 88, therefore, the latch circuits 54 and 64 intended for different scan methods can operate in a single scan method to execute a scan test.

### Third Embodiment

Next, a third embodiment will be described. In the third embodiment, functional parts that are the same as in the first embodiment will be given the same reference characters as in the first embodiment and repeated descriptions will be omitted.

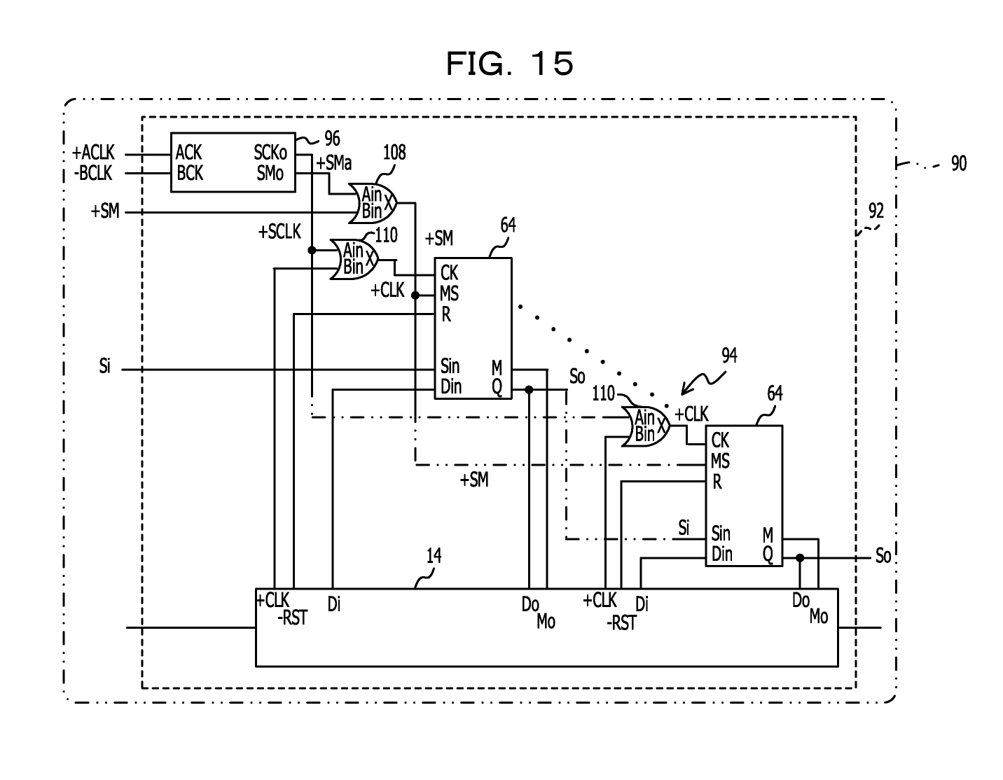

FIG. 15 illustrates a semiconductor integrated circuit 90 in the third embodiment. The semiconductor integrated circuit 90 in the third embodiment functions as an example of a semiconductor integrated circuit. A scan test circuit 92 is formed in the semiconductor integrated circuit 90. A plurality of latch circuits 64 are formed in the scan test circuit 92, forming a scan chain.

The input terminal Din and output terminals Q and M of each latch circuit 64 are connected to the combinational logic circuit 14. The latch circuit 64 operates according to the clock signal +CLK input to the input terminal CK. The input terminal Din or input terminal Sin of the latch circuit 64 is selected according to the mode signal +SM input to the input terminal MS.

If the input terminal Din of the latch circuit 64 is selected, the latch circuit 64 latches data Din received from the combinational logic circuit 14, outputs data Do from the output terminal Q, and outputs data Mo from the output terminal M. If the input terminal Sin of the latch circuit 64 is selected, the latch circuit 64 latches scan data Si input to the input terminal Sin and outputs scan data So from the output terminal Q. The latch circuit 64 in the third embodiment functions as a data latching part controlled in the MUX-D method.

The input terminal R of the latch circuit 64 is connected to the combinational logic circuit 14, so data in the latch circuit 64 is initialized by the reset signal −RST received from the combinational logic circuit 14. As an example in the third embodiment, the input terminal CK of the latch circuit 64 is connected to the combinational logic circuit 14 and the latch circuit 64 operates in synchronization with the clock signal +CLK output from the combinational logic circuit 14.

The scan test circuit 92 includes a latch control part 94. The latch control part 94 may be provided in each latch circuit 64. Alternatively, one latch control part 94 may be shared among a plurality of latch circuits 64. The latch control part 94 in the third embodiment operates as a latch control part. The latch circuit 64 and latch control part 94 in the third embodiment function as a latch circuit.

The latch control part 94 includes a signal creating part 96. The signal creating part 96 includes an input terminal ACK and input terminal BCK. The signal creating part 96 also includes an output terminal SCKo and an output terminal MSo. To operate the latch circuit 64 in the LSSD method, the scan clock signal +ACLK is input to the input terminal ACK of the signal creating part 96 and the scan clock signal −BCLK is input to its input terminal BCK.

The signal creating part 96 receives the scan clock signals +ACLK and −BCLK and creates a clock signal +SCLK and a mode signal +SMa from the received scan clock signals +ACLK and −BCLK. The signal creating part 96 outputs the clock signal +SCLK from the output terminal SCKo and the mode signal +SMa from the output terminal MSo. If the scan clock signals +ACLK and −BCLK function as one of a first control signal and a second control signal, the mode signal +SMa in the third embodiment functions as the other of the first control signal and second control signal.

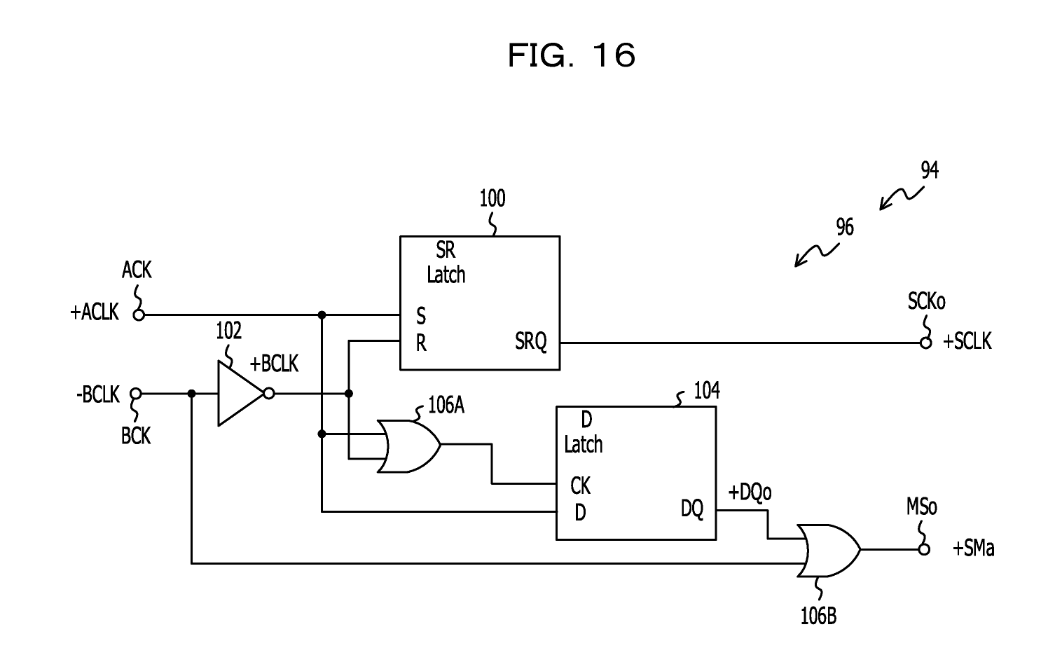

FIG. 16 illustrates an example of the signal creating part 96. The signal creating part 96 includes an SR latch circuit 100 and an inverter circuit 102. The SR latch circuit 100 receives the scan clock signal +ACLK at the input terminal S of the SR latch circuit 100, and also receives the scan clock signal −BCLK at the input terminal R of the SR latch circuit 100 through the inverter circuit 102. In the operation of the SR latch circuit 100, the scan clock signal +ACLK is used as a Set signal and the scan clock signal +BCLK (inverted signal of the scan clock signal −BCLK) is used as a Reset signal. Thus, the SR latch circuit 100 outputs a clock signal +SCLK in synchronization with the scan clock signals +ACLK and +BCLK (−BCLK).

The signal creating part 96 also includes a D latch circuit 104 and OR circuits 106A and 106B. The OR circuit 106A receives the scan clock signal +ACLK and scan clock signal +BCLK. The OR circuit 106A takes the logical product of the scan clock signal +ACLK and scan clock signal +BCLK and outputs the logical product to the input terminal CK of the D latch circuit 104. The D latch circuit 104 receives the scan clock signal +ACLK at the input terminal D of the D latch circuit 104. The D latch circuit 104 retrieves data D by using the scan clock signals +ACLK and +BCLK as clock signals and outputs an output signal +DQo from the output terminal DQ of the D latch circuit 104.

The OR circuit 106B receives the scan clock signal −BCLK and the output signal +DQo output from the D latch circuit 104. The OR circuit 106B takes the logical product of the scan clock signal −BCLK and output signal +DQo and outputs the logical product as the mode signal +SMa.

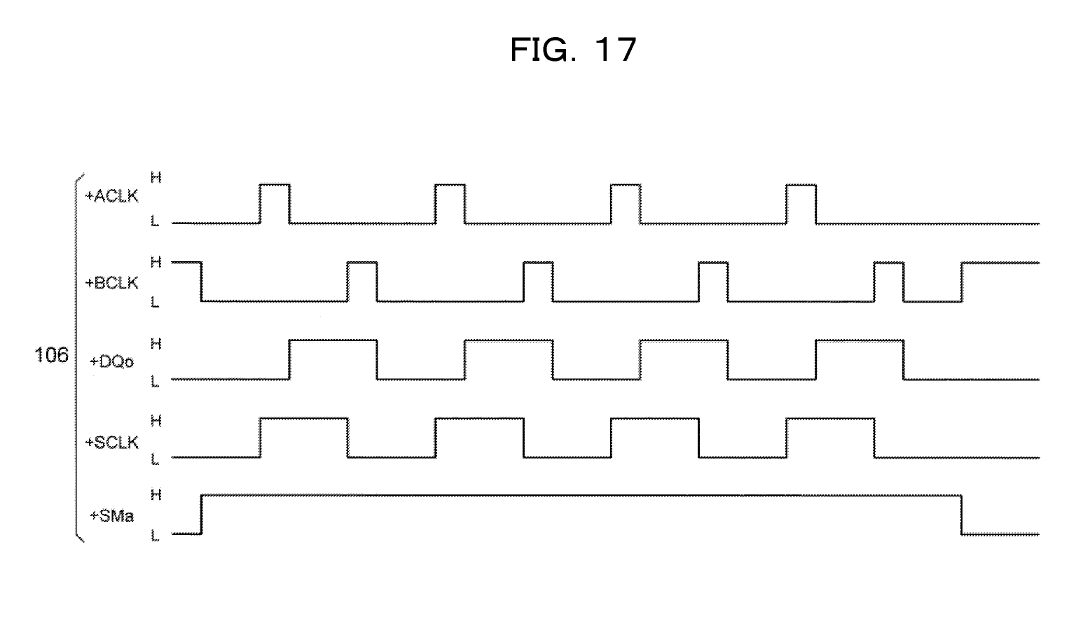

FIG. 17 is a schematic timing diagram of the scan clock signals +ACLK and +BCLK, the output signal DQo from the D latch circuit 104, the clock signal +SCLK, and the mode signal +SMa in the signal creating part 96. The SR latch circuit 100 in the signal creating part 96 creates the clock signal +SCLK in synchronization with the scan clock signals +ACLK and +BCLK. When the scan clock signal +ACLK is held at the H level and the scan clock signal +BCLK is held at the H level (−BCLK=0), the output of the SR latch circuit 100 becomes the L level.

The output signal DQo from the D latch circuit 104 becomes the H level in synchronization with the scan clock signal +ACLK and becomes the L level in synchronization with the scan clock signal +BCLK. Thus, when the scan clock signal −BCLK is input to the OR circuit 106B (the scan clock signal +BCLK is at the L level), the mode signal +SMa output from the OR circuit 106B becomes the H level. When the signal that is input to the OR circuit 106B as the scan clock signal −BCLK is held at the L level (the scan clock signal +BCLK is at the H level), the mode signal +SMa output from the OR circuit 106B becomes the L level.

Referring again to FIG. 15, the latch control part 94 includes an OR circuit 108. The latch control part 94 also includes an OR circuit 110 for each latch circuit 64. The OR circuit 108 receives the mode signal +SMa output from the signal creating part 96 at the input terminal Ain of the OR circuit 108. The OR circuit 108 also receives the mode signal +SM, which is used to operate the scan test circuit 92 in the MUX-D method, at an input terminal Bin of the OR circuit 108. The output terminal X of the OR circuit 108 is connected to the input terminal MS of each latch circuit 64.

Each OR circuit 110 receives the clock signal +SCLK output from the signal creating part 96 at the input terminal Ain of the OR circuit 110. The input terminal Bin of the OR circuit 110 is connected to the combinational logic circuit 14, so the OR circuit 110 receives the clock signal +CLK output from the combinational logic circuit 14 for each latch circuit 64. The output terminal X of the OR circuit 110 is connected to the input terminal CK of its corresponding latch circuit 64.

To operate the scan test circuit 92 in the LSSD method, the scan clock signals +ACLK and −BCLK are input to the latch control part 94. To operate the scan test circuit 92 in the LSSD method, if the input terminal Bin of the OR circuit 108 in the latch control part 94 is at the L level, the OR circuit 108 holds the mode signal +SM input to the input terminal Bin of the OR circuit 108 at a prescribed value (+SM=0).

The signal creating part 96 in the latch control part 94 receives the scan clock signals +ACLK and −BCLK, and outputs the clock signal +SCLK to the OR circuit 108 and the mode signal +SMa to each OR circuit 110.

If the mode signal +SM is not input to the input terminal Bin of the OR circuit 108 in the latch control part 94 and the input terminal Bin is thereby held at the L level, the OR circuit 108 outputs the mode signal +SMa input from the signal creating part 96 to each latch circuit 64 as the mode signal +SM. If the scan clock signals +ACLK and −BCLK are held at the L level, the mode signal +SM output from the latch control part 94 becomes the L level (capture mode). Each OR circuit 110 in the latch control part 94 receives the clock signal +SCLK from the signal creating part 96 and outputs the clock signal +SCLK to its corresponding latch circuit 64 as the clock signal +CLK.

To operate the scan test circuit 92 in the MUX-D method, the mode signal +SM is input to the input terminal Bin of the OR circuit 108 in the latch control part 94. To operate the scan test circuit 92 in the LSSD method, the input terminals ACK and BCK of the signal creating part 96 in the latch control part 94 are held at a prescribed value (L level).

If the scan clock signals +ACLK and −BCLK are not respectively input to the input terminals ACK and BCK of the signal creating part 96 in the latch control part 94 and the input terminals ACK and BCK are held at the L level, the output terminals SCKo and MSo become the L level. When the output terminal MSo of the signal creating part 96 becomes the L level, the input terminal Ain of the OR circuit 108 becomes the L level. When the output terminal SCKo of the signal creating part 96 becomes the L level, the input terminal Ain of each OR circuit 110 becomes the L level.

If the input terminal Ain of the OR circuit 108 is at the L level, the OR circuit 108 outputs the mode signal +SM received at its input terminal Bin to each latch circuit 64. If the input terminal Ain of each OR circuit 110 is at the L level, the OR circuit 110 outputs the clock signal +CLK received at its input terminal Bin to its corresponding latch circuit 64.

As described above, the latch control part 94 outputs the clock signal +CLK and mode signal +SM to each latch circuit 64, regardless of whether the scan test method is the MUX-D method or LSSD method. When the clock signal +CLK and mode signal +SM, which are used to perform a scan test, are input to the latch circuit 64, it operates according to the input clock signal +CLK and mode signal +SM.

Therefore, if the latch control part 94 is connected to the scan control part 18A, the scan test circuit 92 executes a scan test in the LSSD method. By contrast, if the latch control part 94 is connected to the scan control part 18B, the scan test circuit 92 executes a scan test in the MUX-D method.

When the latch circuit 64 operating in the MUX-D method is built into the semiconductor integrated circuit 90 together with the latch control part 94, it becomes possible to operate the latch circuit 64 in any one of the MUX-D method and LSSD method.

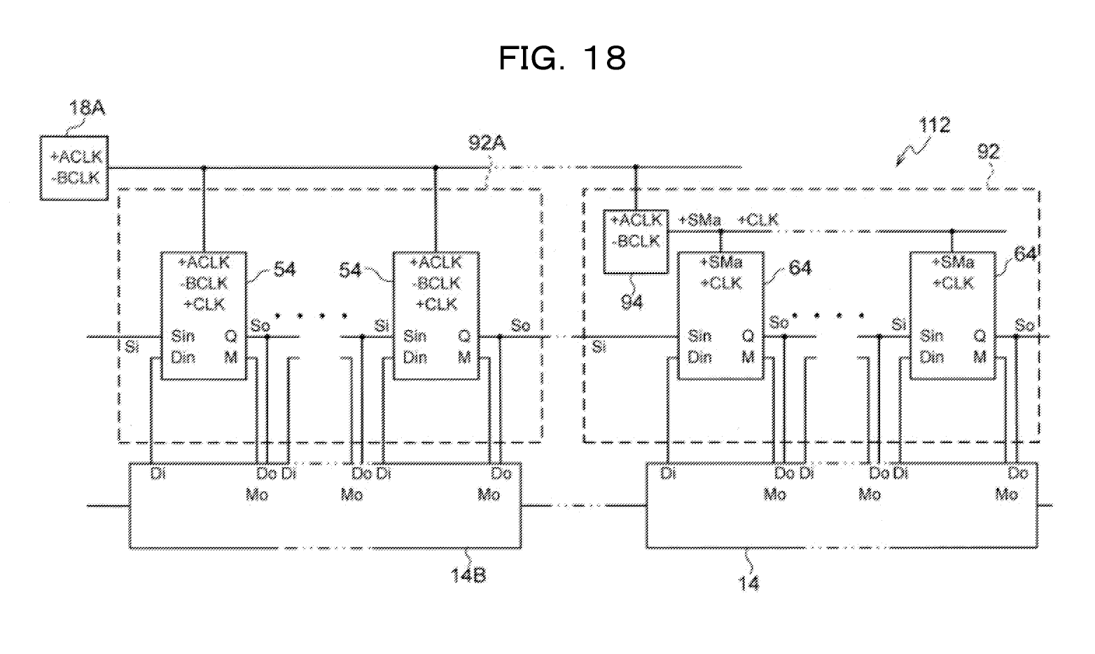

FIG. 18 illustrates a scan test circuit 112 in which latch circuits 64 and the latch control part 94 are used. The scan test circuit 112 includes the scan test circuit 92 and a scan test circuit 92A. In the scan test circuit 92A, a scan chain is formed by a plurality of latch circuits 54, each of which operates in the LSSD method.

Each latch circuit 64 in the scan test circuit 92 is connected to the combinational logic circuit 14, and each latch circuit 54 in the scan test circuit 92A is connected to a combinational logic circuit 14B. In the scan test circuit 112, the input terminal Sin of the latch circuit 64 at, for example, the foremost stage in the scan test circuit 92 is connected to the latch circuit 54 at the last stage in the scan test circuit 92A.

The scan test circuit 92 and scan test circuit 92A are connected to the scan control part 18A, which executes a scan test in the LSSD method. The scan control part 18A outputs the scan clock signals +ACLK and −BCLK to each latch circuit 54 in the scan test circuit 92A. The operation of the latch circuit 54 is controlled by the scan control part 18A accordingly.

In the scan test circuit 92, the latch control part 94 is connected to the scan control part 18A and each latch circuit 64 is connected to the latch control part 94. If the input terminal Bin of the OR circuit 108 is at the L level, the latch control part 94 holds the mode signal +SM received at the input terminal Bin of the OR circuit 108 at a prescribed value (+SM=0). The latch control part 94 creates the clock signal +SCLK and mode signal +SMa from the scan clock signals +ACLK and −BCLK that are input from the scan control part 18A and outputs the created clock signal +SCLK and mode signal +SMa to each latch circuit 64.

The operation of the latch circuit 64 is controlled by the clock signal +CLK and mode signal +SM received from the latch control part 94. In the scan test circuit 92, the latch circuits 54 operate according to control signals in the MUX-D method and execute a scan test.

In the scan test circuit 112, since the latch control part 94 is provided for the latch circuits 64, which operate in the MUX-D method, the scan test circuit 92 operates in the LSSD method in the same way as with the scan test circuit 92A.

In the scan test circuit 112, therefore, the latch circuits 54 and 64 intended for different scan methods can operate in a single scan method (LSSD method) and execute a scan test.

To design the semiconductor integrated circuit 10 or the like, an electronic design automation (EDA) tool, for example, is used. If, in the EDA tool, a certain function circuit block is created and retained in advance as, for example, as a circuit block and the circuit block created in advance is included during the design of the semiconductor integrated circuit 10 or the like, the design efficiency can be improved. In this case, the latch circuit 16 including the data latching part 20 and latch control part 22 is retained as a single circuit block, a circuit including the latch circuit 54 and latch control part 74 is retained as a single circuit block, and a circuit including the latch circuit 64 and latch control part 94 is retained as a single circuit block.

If the circuit blocks retained in this way are built into the semiconductor integrated circuit 10 or the like as latch circuits, both the LSSD method and MUX-D method can be applied to the design of a scan test circuit such as, for example, the semiconductor integrated circuit 10 as the scan method. Accordingly, even if latch circuits in different scan methods are mounted in the semiconductor integrated circuit 10 or the like, any one of these scan methods can be used, enabling a scan test circuit to be very easily designed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A latch circuit, comprising:
a data latch that holds data that has been input according to one of a first control signal and a second control signal; and
a latch controller that comprises:
a first input terminal to which a first operation signal is input, the first operation signal operating the data latch in a first scan method, and
a second input terminal to which a second operation signal is input, the second operation signal operating the data latch in a second scan method; wherein
when a prescribed value is input to the first input terminal and the second operation signal is input to the second input terminal, the latch controller outputs the second control signal to control the data latch, and
when a prescribed value is input to the second input terminal and the first operation signal is input to the first input terminal, the latch controller outputs the first control signal to control the data latch.

2. The latch circuit according to claim 1, wherein:
the data latch comprises:
a first switch that operates to retrieve first data,
a second switch that operates to retrieve second data,
a first latch that holds the first data retrieved from the first switch or the second data retrieved from the second switch,
a third switch that operates to retrieve the first data or the second data held by the first latch, and
a second latch that holds the first data retrieved from the first switch and the second data retrieved from the second switch and outputs the one of the first data and the second data that has been held; and
the latch controller outputs, as the first control signal, a first operation control signal used to operate the first switch, a second operation control signal used to operate the second switch, and a third operation control signal used to operate the third switch, or outputs, as the second control signal, a fourth operation control signal used to operate the first switch, a fifth operation control signal used to operate the second switch, and a sixth operation control signal used to operate the third switch.

3. The latch circuit according to claim 1, wherein one of the first operation signal and the second operation signal comprises a scan mode signal that makes a switchover to selectively retrieve one of the first data and the second data, and another of the first operation signal and the second operation signal comprises two scan clock signals, time durations of which differ from each other.

4. A latch circuit, comprising:
a data latch that holds data that has been input according to one of a first control signal and a second control signal; and
a latch controller that comprises:
a first input terminal to which a first operation signal is input, the first operation signal operating the data latch in a first scan method, and
a second input terminal to which a second operation signal is input, the second operation signal operating the data latch in a second scan method; wherein
the data latch is controlled only by the first control signal; and
when the prescribed value is input to the first input terminal and the second operation signal is input to the second input terminal, the latch controller outputs the first control signal according to the second operation signal.

5. A scan test circuit, comprising:
a plurality of data latches, each of which holds data that has been input according to one of a first control signal and a second control signal; and
a latch controller that comprises:
a first input terminal to which a first operation signal is input, the first operation signal operating the data latches in a first scan method, and
a second input terminal to which a second operation signal is input, the second operation signal operating the data latches in a second scan method; wherein
when a prescribed value is input to the first input terminal and the second operation signal is input to the second input terminal, the latch controller outputs the second control signal to control each of the plurality of data latches, and
when a prescribed value is input to the second input terminal and the first operation signal is input to the first input terminal, the latch controller outputs the first control signal to control the each of the plurality of data latches.

6. The scan test circuit according to claim 5, wherein:
the data latch comprises:
a first switch that operates to retrieve first data output from a combinational logic circuit,
a second switch that operates to retrieve second data,
a first latch that holds one of the first data retrieved from the first switch and the second data retrieved from the second switch,
a third switch that operates to retrieve the first data or the second data held by the first latch, and
a second latch that holds the first data retrieved from the first switch or the second data retrieved from the second switch and outputs the one of the first data and the second data that has been held; and
the latch controller outputs, as the first control signal, a first operation control signal used to operate the first switch, a second operation control signal used to operate the second switch, and a third operation control signal used to operate the third switch, or outputs, as the second control signal, a fourth operation control signal used to operate the first switch, a fifth operation control signal used to operate the second switch, and a sixth operation control signal used to operate the third switch.

7. The scan test circuit according to claim 5, further comprising a scan controller that the outputs the first operation signal to the first input terminal of the latch controller and outputs the second operation signal to the second input terminal of the latch controller.

8. A scan test circuit, comprising:
a plurality of data latches, each of which holds data that has been input according to one of a first control signal and a second control signal; and
a latch controller that comprises:
a first input terminal to which a first operation signal is input, the first operation signal operating the data latches in a first scan method, and
a second input terminal to which a second operation signal is input, the second operation signal operating the data latches in a second scan method; wherein
the each of the plurality of data latches is controlled only by the first control signal; and
when the prescribed value is input to the first input terminal and the second operation signal is input to the second input terminal, the latch controller outputs the first control signal according to the second operation signal.

9. A scan test circuit, comprising:
a first scan test circuit that comprises a plurality of first data latches, each of which holds data that has been input according to a first control signal;
a second scan test circuit that comprises:
a plurality of second data latches, each of which holds data that has been input according to a second control signal, and
a latch controller that comprises a first input terminal to which a first operation signal is input, the first operation signal operating the second data latch in a first scan method, and a second input terminal to which a second operation signal is input, the second operation signal operating the second data latch in a second scan method, the latch controller being configured to output the first control signal to control each of the plurality of second data latches when a prescribed value is input to the second input terminal and the first operation signal is input to the first input terminal; and
a scan controller that outputs the first operation signal to each of the plurality of first data latches in the first scan test circuit and to the latch controller in the second scan test circuit.

10. The scan test circuit according to claim 9, wherein one of the first operation signal and the second operation signal comprises a scan mode signal that makes a switchover to selectively retrieve one of the first data and the second data as data to be held, and another of the first operation signal and the second operation signal comprises two scan clock signals, time durations of which differ from each other.

11. A scan test circuit, comprising:
a plurality of data latches to be tested and coupled in a scan chain; and
a latch controller controlling the latches to selectively perform one of a level sensitive scan design (LSSD) method and a multiplexer D (MUXD) method, where the MUX-D method produces latch control using a system clock and a scan mode signal and the LSSD method produces latch control using the system clock and first and second scan signals each having different durations.

12. A latch circuit control method comprising
controlling each of a plurality of data latches included in a latch circuit, each data latch being configured to hold data that has been input according to a first control signal or a second control signal, by outputting, when a first operation signal used to operate the each of the plurality of data latches in a first scan method has a prescribed value and a second operation signal used to operate the each of the plurality of data latches in a second scan method is input, the second control signal corresponding to the second operation signal; and
controlling the each of the plurality of data latches by, when the second operation signal has a prescribed value and the first operation signal is input, the first control signal corresponding to the first operation signal.

13. A latch circuit control method comprising
controlling each of a plurality of data latches included in a latch circuit, each data latch being configured to hold data that has been input according to a first control signal or a second control signal, by outputting, when a first operation signal used to operate the each of the plurality of data latches in a first scan method has a prescribed value and a second operation signal used to operate the each of the plurality of data latches in a second scan method is input, the second control signal corresponding to the second operation signal; and
if the each of a plurality of data latches is controlled by the first control signal,
when the first operation signal has a prescribed value and the second operation signal is input, the each of a plurality of data latches is controlled by outputting the first control signal according to the second operation signal, and
when the second operation signal has a prescribed value and the first operation signal is input, the each of the plurality of data latches is controlled by outputting the first operation signal as the first control signal.
